(19) United States
(12) Patent Application Publication
(10) Pub. No.: US 2017/0040232 A1
(43) Pub. Date: Feb. 9, 2017

(54) METHOD OF MANUFACTURING SEMICONDUCTOR DEVICE

(71) Applicant: HITACHI KOKUSAI ELECTRIC INC., Tokyo (JP)

(72) Inventors: Masanori NAKAYAMA, Toyama-shi (JP); Toshiyuki KIKUCHI, Toyama-shi (JP); Atsuhiko SUDA, Toyama-shi (JP); Kazuyuki TOYODA, Toyama-shi (JP); Shun MATSUI, Toyama-shi (JP)

(73) Assignee: HITACHI KOKUSAI ELECTRIC INC., Tokyo (JP)

(21) Appl. No.: 15/229,590

(22) Filed: Aug. 5, 2016

(30) Foreign Application Priority Data
Aug. 7, 2015 (JP) 2015-156551

(51) Int. Cl. H01L 21/66; H01L 21/306

(52) U.S. Cl. CPC H01L 22/20; H01L 22/12; H01L 21/30625

(57) ABSTRACT

A technique is provided in which a deviation of a characteristic of a semiconductor device is suppressed from occurring. The technique includes a method of a manufacturing a semiconductor device, including: (a) polishing a first silicon-containing layer formed on a substrate including a convex structure; (b) obtaining a data representing a height distribution of a surface of the first silicon-containing layer after performing the step (a); (c) determining a process condition; and (d) supplying a process gas to form a second silicon-containing layer wherein the process gas is activated such that a concentration of an active species of the process gas at a center portion of the substrate differs from a concentration of an active species at a peripheral portion of the substrate to adjust heights of surfaces of a laminated film according to the process condition.

### CROSS-REFERENCE TO RELATED PATENT APPLICATION

This non-provisional U.S. patent application claims priority under 35 U.S.C. §119 of Japanese Patent Application No. 2015-156551, filed on Aug. 7, 2015, the entire contents of which are hereby incorporated by reference.

### BACKGROUND

1. Field

The present disclosure relates to a method of manufacturing a semiconductor device.

2. Description of the Related Art

Recently, a degree of integration of a semiconductor device is being increased and thus a size of a pattern is being significantly miniaturized. The miniaturized pattern is formed by processes such as a process of forming a hard mask or a resist layer, a photolithography process and an etching process. In forming the pattern, it is required that a deviation of a line width of the pattern does not occur. A variation of the line width of the pattern is caused by a variation of a characteristic of the semiconductor device.

### SUMMARY

Due to problems in a manufacturing process, a variation of a line width of a pattern such as a circuit formed in a semiconductor device may occur. When a variation of the line width of the pattern occurs, a characteristic of the semiconductor device including a miniaturized pattern are significantly affected.

Described herein is a technique in which a deviation of the characteristic of the semiconductor device is suppressed from occurring.

According to one aspect, there is provided a technique including a method of manufacturing a semiconductor device, including: (a) polishing a first silicon-containing layer formed on a substrate including a convex structure; (b) obtaining a data representing a height distribution of a surface of the first silicon-containing layer after performing the step (a); (c) determining a process condition based on the data for reducing a difference between a height of a surface of a laminated film at a center portion of the substrate and the height of the surface of the laminated film at a peripheral portion of the substrate, wherein the laminated film includes the first silicon-containing layer and a second silicon-containing layer to be formed on the first silicon-containing layer in step (d), the second silicon-containing layer containing a chemical compound different from that of the first silicon-containing layer; and (d) supplying a process gas to form the second silicon-containing layer wherein the process gas is activated such that a concentration of an active species of the process gas at the center portion of the substrate differs from a concentration of an active species at the peripheral portion of the substrate to adjust the heights of the surfaces of the laminated film according to the process condition.

### BRIEF DESCRIPTION OF THE DRAWINGS

FIG. 1 is a flowchart illustrating a first embodiment of a method of manufacturing a semiconductor device described herein.

FIGS. 2A and 2B are views exemplifying a wafer to be processed by the first embodiment of the method of manufacturing the semiconductor device described herein, where FIG. 2A is a perspective view illustrating a portion of a structure formed on the wafer and FIG. 2B is a cross-sectional view taken along line α-α′ of FIG. 2A.

FIGS. 3A through 3C are a view exemplifying a state of the wafer processed by the first embodiment of the method of manufacturing the semiconductor device described herein, where FIG. 3A is a view illustrating the wafer in a state in which a gate insulating film is formed, FIG. 3B is a view illustrating the wafer in a state in which a first silicon-containing layer is formed, and FIG. 3C is a view illustrating the wafer in a state in which polishing is performed on the first silicon-containing layer.

FIG. 4 is a view illustrating a schematic configuration of a chemical mechanical polishing (CMP) apparatus used in the first embodiment described herein.

FIG. 5 is a view exemplifying a configuration of a polishing head included in the CMP apparatus used in the first embodiment described herein and a peripheral structure thereof.

FIG. 6 is a view exemplifying a height distribution of a first silicon-containing layer after polishing in the first embodiment described herein.

FIGS. 7A and 7B are views illustrating a first example of a laminated film after a second silicon-containing layer is formed in the first embodiment described herein, where FIG. 7A is a top view illustrating the wafer after the second silicon-containing layer is formed and FIG. 7B is a cross-sectional view taken along line α-α′ of FIG. 7A.

FIG. 8 is a view illustrating a first example of a height distribution of the second silicon-containing layer in the first embodiment described herein.

FIGS. 9A and 9B are views illustrating a second example of the laminated film after the second silicon-containing layer is formed in the first embodiment described herein, where FIG. 9A is a top view illustrating the wafer after the second silicon-containing layer is formed and FIG. 9B is a cross-sectional view taken along line α-α′ of FIG. 9A.

FIG. 10 is a view illustrating a second example of the height distribution of the second silicon-containing layer in the first embodiment described herein.

FIG. 11 is a block diagram illustrating a configuration of the first embodiment of a substrate processing system described herein.

FIG. 12 is a flowchart exemplifying processing of the first embodiment of the substrate processing system described herein.

FIG. 13 is a view schematically illustrating a configuration of a substrate processing apparatus of the first embodiment of the substrate processing system described herein.

FIG. 14 is a view schematically illustrating a first example of a substrate support of the substrate processing apparatus of the first embodiment of the substrate processing system described herein.

FIG. 15 is a view schematically illustrating a second example of the substrate support of the substrate processing apparatus of the first embodiment of the substrate processing system described herein.

FIG. 16 is a view schematically illustrating an exemplary configuration of a gas supply unit of the substrate processing apparatus of the first embodiment of the substrate processing system described herein.

FIG. 17 is a view schematically illustrating an exemplary configuration of a controller of the substrate processing apparatus of the first embodiment of the substrate processing system described herein.

FIG. 18 is a flowchart exemplifying processing of the substrate processing apparatus of the first embodiment of the substrate processing system described herein.

FIG. 19 is a view illustrating an example of an adjustment (a tuning) performed in the substrate processing apparatus of the first embodiment of the substrate processing system described herein in detail.

FIGS. 20A and 20B are views illustrating the wafer after a laminated film is formed in a first specific example of the first embodiment of the method of manufacturing the semiconductor device described herein, where FIG. 20A is a top view illustrating the wafer and FIG. 20B is a cross-sectional view taken along line α-α′ of FIG. 20A.

FIGS. 21A and 21B are views illustrating the wafer after an exposure process is performed in the first specific example of the first embodiment of the method of manufacturing the semiconductor device described herein, where FIG. 21A is a top view illustrating the wafer and FIG. 21B is a cross-sectional view taken along line α-α′ of FIG. 21A.

FIGS. 22A and 22B are views illustrating the wafer after an etching process is performed in the first specific example of the first embodiment of the method of manufacturing the semiconductor device described herein, where FIG. 22A is a top view illustrating the wafer and FIG. 22B is a cross-sectional view taken along line α-α′ of FIG. 22A.

FIGS. 23A and 23B are views illustrating the wafer after an exposure process is performed in a first comparative example compared with the first specific example in the first embodiment described herein, where FIG. 23A is a top view illustrating the wafer and FIG. 23B is a cross-sectional view taken along line α-α′ of FIG. 23A.

FIGS. 24A and 24B are views illustrating the wafer after an etching process is performed in a second comparative example compared with the first embodiment described herein, where FIG. 24A is a top view illustrating the wafer and FIG. 24B is a cross-sectional view taken along line α-α′ of FIG. 24A.

FIGS. 25A and 25B are views illustrating the wafer after an adjustment (a tuning) is performed in a third comparative example compared with the first embodiment described herein, where FIG. 25A is a top view illustrating the wafer and FIG. 25B is a cross-sectional view taken along line α-α′ of FIG. 25A.

FIG. 26 is a view illustrating an example of an adjustment (a tuning) performed by a substrate processing apparatus in a second embodiment of the method of manufacturing the semiconductor device described herein in detail.

FIG. 27 is a view illustrating an example of an adjustment (a tuning) performed by a substrate processing apparatus in a third embodiment of the method of manufacturing the semiconductor device described herein in detail.

FIG. 28 is a view illustrating an example of an adjustment (a tuning) performed by a substrate processing apparatus in a fourth embodiment of the method of manufacturing the semiconductor device described herein in detail.

FIG. 29 is a view illustrating an example of an adjustment (a tuning) performed by a substrate processing apparatus in a fifth embodiment of the method of manufacturing the semiconductor device described herein in detail.

FIG. 30 is a view illustrating an example of an adjustment (a tuning) performed by a substrate processing apparatus in a sixth embodiment of the method of manufacturing the semiconductor device described herein in detail.

FIG. 31 is a view illustrating an example of an adjustment (a tuning) performed by a substrate processing apparatus in a seventh embodiment of the method of manufacturing the semiconductor device described herein in detail.

FIG. 32 is a view illustrating an example of an adjustment (a tuning) performed by a substrate processing apparatus in an eighth embodiment of the method of manufacturing the semiconductor device described herein in detail.

FIG. 33 is a view illustrating an example of an adjustment (a tuning) performed by a substrate processing apparatus in a ninth embodiment of the method of manufacturing the semiconductor device described herein in detail.

FIG. 34 is a view exemplifying a configuration of the substrate processing system described herein.

### DETAILED DESCRIPTION OF THE PREFERRED EMBODIMENTS

Hereinafter, embodiments described herein will be described with reference to the drawings.

(1) Method of Manufacturing Semiconductor Device

First, a first embodiment of a method of manufacturing a semiconductor device described herein will be described. The first embodiment is a method of manufacturing a semiconductor device such as a fin field effect transistor (FinFET).

(Overview of FinFET Manufacturing)

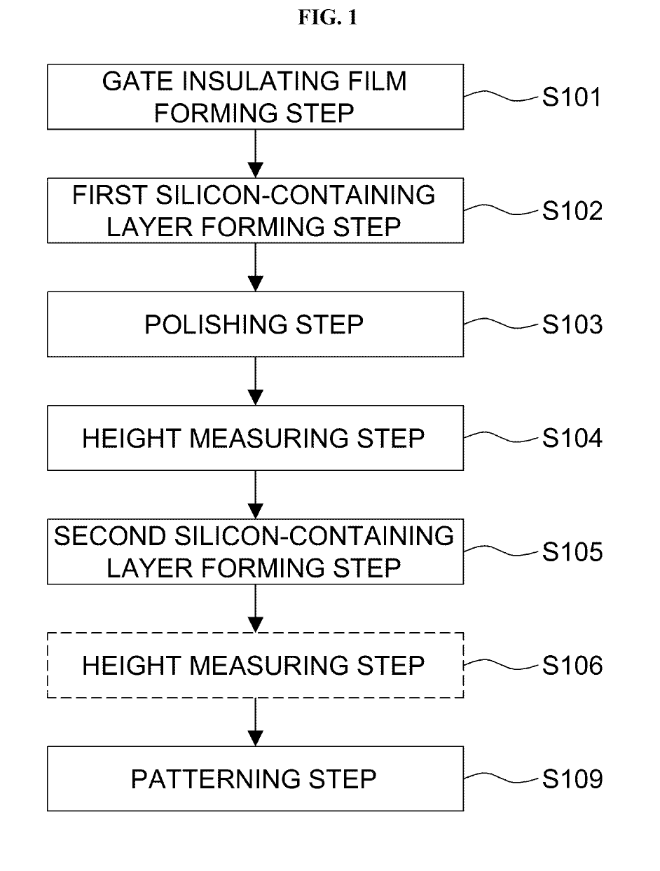

A FinFET is formed on, for example, a substrate (hereinafter simply referred to as a “wafer”) serving as a 300 mm wafer in which a convex structure (a Fin structure) is formed. As illustrated in FIG. 1, the FinFET is manufactured by sequentially performing at least a gate insulating film forming step S101, a first silicon-containing layer forming step S102, a polishing step S103, a height measuring step S104, a second silicon-containing layer forming step S105, a height measuring step S106 (performed when necessary) and a patterning step S109. Hereinafter, each of the steps S101 to S109 will be described.

[Gate Insulating Film Forming Step S101]

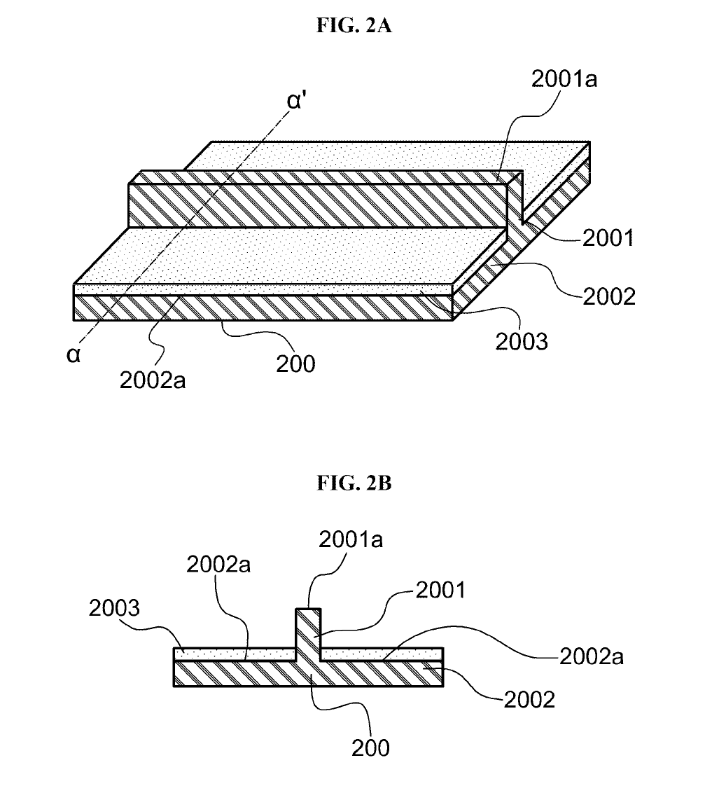

In the gate insulating film forming step S101, a gate insulating film is formed on, for example, a wafer 200 including a structure illustrated in FIGS. 2A and 2B.

The wafer 200 is manufactured of a material such as silicon and a convex structure 2001 (a Fin structure) serving as a channel is formed on a portion of the wafer 200. A plurality of convex structures 2001 are installed at a predetermined interval. The convex structures 2001 are formed by patterning (etching) the portion of the wafer 200. In this specification, for convenience of description, a portion having none of the convex structures 2001 on the wafer 200 is referred to as a concave structure 2002. That is, the wafer 200 includes at least the convex structure 2001 and the concave structure 2002. In this specification, for convenience of description, an upper surface of the convex structure 2001 is called a convex structure surface 2001a and an upper surface of the concave structure 2002 is called a concave structure surface 2002a. A device isolation film 2003 is formed on the concave structure surface 2002a disposed between adjacent convex structures 2001. The device isolation film 2003 electrically isolates the adjacent convex structures 2001 from each other. The device isolation film 2003 includes, for example, a silicon oxide film.

The gate insulating film is formed using a gate insulating film forming apparatus. When the gate insulating film is formed, the wafer 200 including the convex structure 2001 and the concave structure 2002 is loaded into the gate insulating film forming apparatus. The gate insulating film forming apparatus may include a well-known single wafer apparatus capable of forming a thin film. A detailed description of the gate insulating film forming apparatus will be omitted.

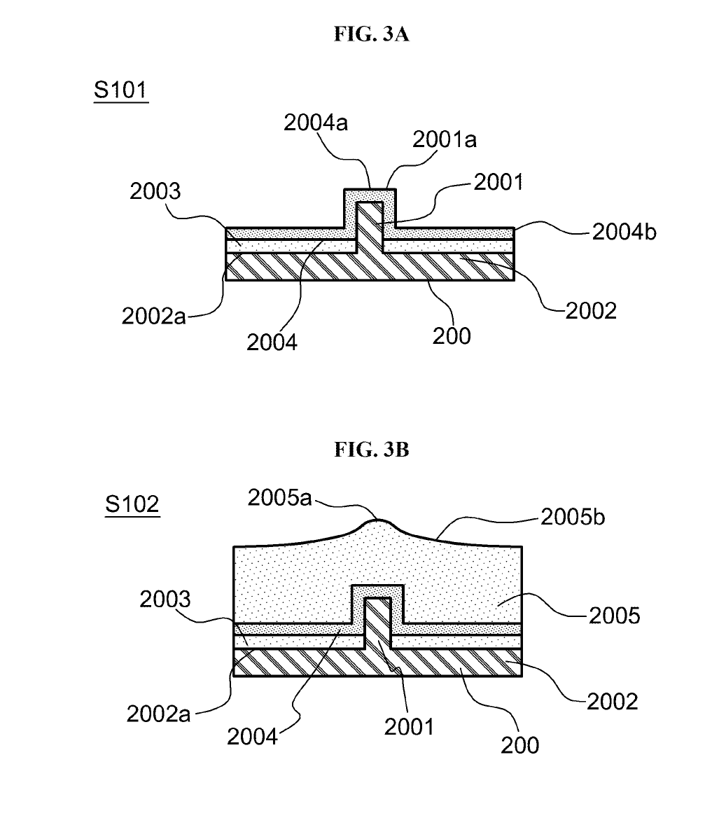

A gate insulating film 2004 made of a dielectric, such as a silicon oxide film (a SiO₂ film) illustrated in FIG. 3A, is formed by the gate insulating film forming apparatus. The gate insulating film 2004 is formed by supplying a silicon-containing gas [e.g., HCDS (hexachlorodisilane) gas] and an oxygen-containing gas (e.g., O₃ gas) to the gate insulating film forming apparatus. The gate insulating film 2004 is formed by reacting the silicon-containing gas with the oxygen-containing gas. The gate insulating film 2004 is formed on an upper surface of the wafer 200, that is, on each of the convex structure surface 2001a and the concave structure surface 2002a. After the gate insulating film is formed, the wafer 200 is unloaded from the gate insulating film forming apparatus.

[First Silicon-Containing Layer Forming Step S102]

As illustrated in FIG. 3B, in the first silicon-containing layer forming step S102, a first silicon-containing layer 2005 is formed on the gate insulating film 2004.

The first silicon-containing layer 2005 is formed using a first silicon-containing layer forming apparatus. The wafer 200 unloaded from the gate insulating film forming apparatus is loaded into the first silicon-containing layer forming apparatus and the first silicon-containing layer 2005 is formed. The first silicon-containing layer forming apparatus may include a general single wafer chemical vapor deposition (CVD) apparatus. A detailed description of the first silicon-containing layer forming apparatus will be omitted.

For example, the first silicon-containing layer 2005 (hereinafter also referred to as a “poly-Si layer”) including poly-Si [polycrystalline silicon] is formed on the gate insulating film 2004 by the first silicon-containing layer forming apparatus. The first silicon-containing layer 2005 is formed by supplying disilane (Si₂H₆) gas to the first silicon-containing layer forming apparatus. The poly-Si layer 2005 is formed on the gate insulating film 2004 by pyrolyzing the disilane (Si₂H₆) gas. The poly-Si layer 2005 which is formed includes a poly-Si layer 2005a which is a film laminated on the convex structure surface 2001a, more specifically, on a gate insulating film 2004a on the convex structure surface 2001a and a poly-Si layer 2005b which is a film laminated on the concave structure surface 2002a, more specifically, on a gate insulating film 2004b on the concave structure surface 2002a. After the poly-Si layer 2005 is formed, the wafer 200 is unloaded from the first silicon-containing layer forming apparatus.

The first silicon-containing layer (the poly-Si layer) 2005 is a dummy gate electrode for manufacturing a FinFET. After patterning to be described below is performed, the first silicon-containing layer 2005 is finally removed.

[Polishing Step S103]

The first silicon-containing layer 2005 is polished in the polishing step S103.

As described above, the wafer 200 includes the convex structure 2001 and the concave structure 2002. Therefore, a height of a surface of the poly-Si layer 2005 formed in the first silicon-containing layer forming step S102 varies at each portion of the surface of the wafer 200. Specifically, a distance between the concave structure surface 2002a and a surface of the poly-Si layer 2005a formed on the convex structure 2001 is greater than a distance between the concave structure surface 2002a and a surface of the poly-Si layer 2005b formed on the concave structure surface 2002a. However, because of a relationship of at least one of an exposure process and an etching process to be described below, a height of the surface of the poly-Si layer 2005a has to be the same as a height of the surface of the poly-Si layer 2005b. As illustrated in FIG. 3C, the surface of the poly-Si layer 2005 is polished in the polishing step S103 so that a difference between the height of the surface of the poly-Si layer 2005a and the height of the surface of the poly-Si layer 2005b does not occur.

The poly-Si layer 2005 is polished using a chemical mechanical polishing (CMP) apparatus. That is, the wafer 200 unloaded from the first silicon-containing layer forming apparatus is loaded into the CMP apparatus and the poly-Si layer 2005 is polished.

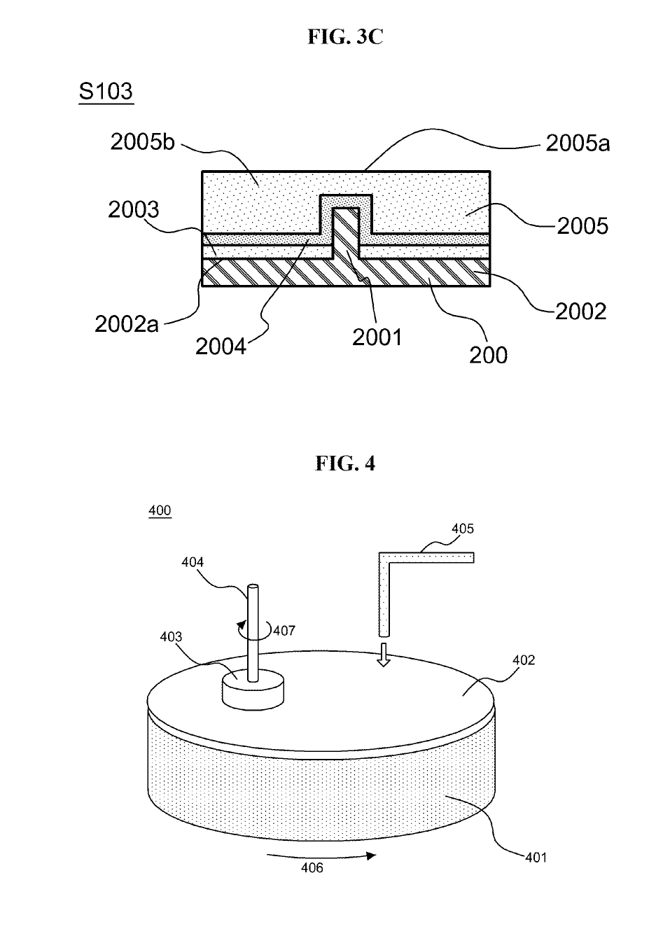

As illustrated in FIG. 4, the CMP apparatus includes a polishing plate 401 with a polishing cloth 402 mounted on an upper surface thereof. The polishing plate 401 is connected to a rotating mechanism (not illustrated). While polishing the wafer 200, the polishing plate 401 rotates in a direction of an arrow 406 of FIG. 4. The CMP apparatus further includes a polishing head 403 disposed at a position facing the polishing cloth 402. The polishing head 403 is connected to the rotating mechanism (not illustrated) and a vertical driving mechanism (not illustrated) through a shaft 404 connected to an upper surface thereof. While polishing the wafer 200, the polishing head 403 rotates in a direction of an arrow 407 of FIG. 4. The CMP apparatus further includes a supply pipe 405 which supplies a slurry (an abrasive). While the wafer 200 is being polished, the slurry is supplied to the polishing cloth 402 through the supply pipe 405.

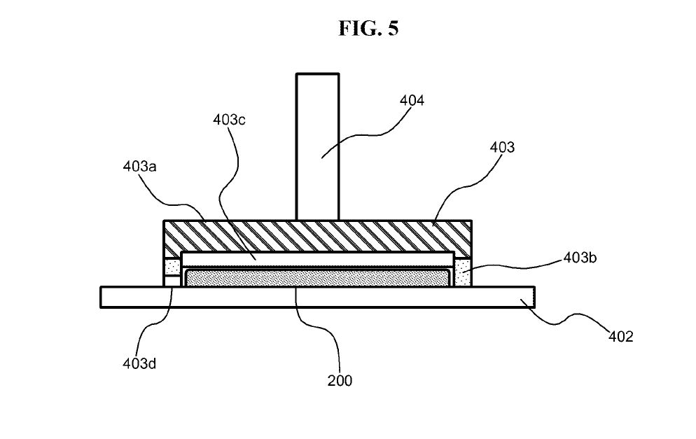

As illustrated in FIG. 5, the polishing head 403 of the CMP apparatus includes a top ring 403a, a retainer ring 403b and an elastic mat 403c. The retainer ring 403b surrounds a peripheral portion of the wafer 200 that is being polished and the elastic mat 403c holds the wafer 200 down on the polishing cloth 402. A groove 403d through which the slurry passes is provided in the retainer ring 403b from an outside of the retainer ring 403b toward an inside thereof. A plurality of grooves 403d are installed in a cylindrical shape to match a shape of the retainer ring 403b. Used slurry is replaced by fresh slurry inside the retainer ring 403b through the grooves 403d.

Processing performed in the CMP apparatus of the above-described configuration will be described. When the wafer 200 is loaded into the polishing head 403 of the CMP apparatus, the polishing plate 401 and the polishing head 403 rotate while the slurry is supplied through the supply pipe 405. Thus, the slurry is supplied into the retainer ring 403b and polishes the surface of the poly-Si layer 2005 on the wafer 200. That is, as illustrated in FIG. 3C, the CMP apparatus polishes the surface of the poly-Si layer 2005 so that a height of the poly-Si layer 2005a is the same as a height of the poly-Si layer 2005b. The “height” refers to the height of the surface (the upper surface) of each of the poly-Si layer 2005a and the poly-Si layer 2005b. After polishing for a predetermined time, the wafer 200 is unloaded from the CMP apparatus.

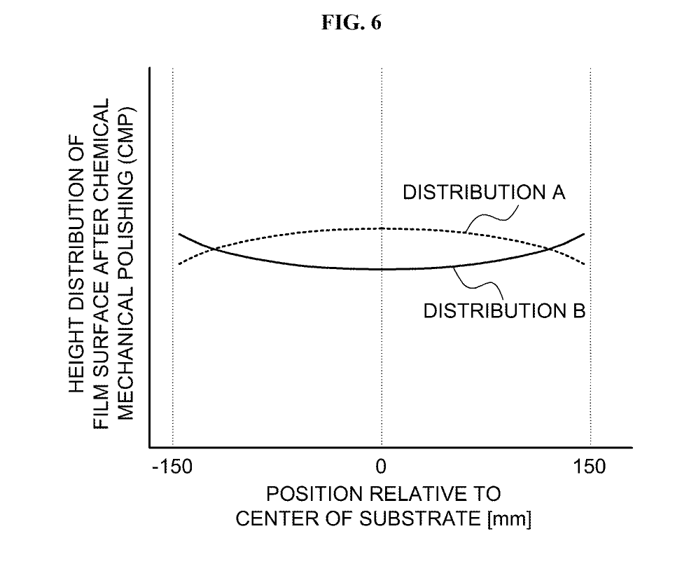

Even when the wafer 200 is polished so that the height of the poly-Si layer 2005a is the same as the height of the poly-Si layer 2005b using the CMP apparatus, the height of the surface of the poly-Si layer 2005 after the polishing may not be constant on the surface of the wafer 200. Specifically, as illustrated in FIG. 6, there may be a height distribution [“distribution A” of FIG. 6] in which a height of a film surface at a peripheral portion of the wafer 200 is smaller than a height of a film surface at a center portion thereof or a height distribution [“distribution B” of FIG. 6] in which the height of the film surface at the center portion of the wafer 200 is smaller than the height of the film surface at the peripheral portion thereof. A problem in that a variation of the height of the film surface results in a variation of a line width of a pattern formed through a process such as an exposure process or an etching process to be described below may occur. Due to the variation of the line width of the pattern, a variation of a width of a gate electrode occurs, and thus there is a problem in that a yield of the FinFET is decreased. According to the results of intensive research by the inventors of the present application, they found that the following causes for the distribution A and the distribution B exist.

A method of supplying the slurry to the wafer 200 is the cause of the distribution A. As described above, the slurry supplied to the polishing cloth 402 is supplied to the peripheral portion of the wafer 200 through the retainer ring 403b. Therefore, while the unused slurry is supplied to the peripheral portion of the wafer 200, the slurry that polished the peripheral portion of the wafer 200 is supplied to the center portion of the wafer 200. Since the unused slurry has a high polishing efficiency, the peripheral portion of the wafer 200 is polished more than the center portion thereof. Therefore, the height distribution of the surface of the poly-Si layer 2005 becomes like the distribution A.

Wear of the retainer ring 403b is the cause of the distribution B. When a plurality of wafers 200 are polished through the CMP apparatus, a front end of the retainer ring 403b held down on the polishing cloth 402 is worn, and thus a surface in contact with the groove 403d or the polishing cloth 402 is deformed. Therefore, the slurry originally designed to be supplied is not supplied to an inner peripheral portion of the retainer ring 403b. In this case, since the slurry is not supplied to the peripheral portion of the wafer 200, the center portion of the wafer 200 is polished more and the peripheral portion thereof is not polished. From the above, the height distribution of the surface of the poly-Si layer 2005 becomes like the distribution B.

As described above, although a structure of the CMP causes the height distribution of the film surface such as the distribution A or the distribution B, it is difficult to change the structure of the CMP apparatus. Therefore, according to the first embodiment, a variation of the height of the surface of the poly-Si layer 2005 is corrected by performing the height measuring step S104 and the second silicon-containing layer forming step S105 on the poly-Si layer 2005 polished in the polishing step S103.

[Height Measuring Step S104]

In the height measuring step S104, the height of the first silicon-containing layer (the poly-Si layer) 2005 polished in the polishing step S103 is measured, and data that indicates the height distribution of the surface of the poly-Si layer 2005 on the wafer 200 (hereinafter simply referred to as “height distribution data of the film surface” or “height distribution data”) based on the measured result is obtained.

A height measuring apparatus measures the height of the film surface. The wafer 200 unloaded from the CMP apparatus is loaded into the height measuring apparatus, and the height of the surface of the poly-Si layer 2005 is measured. For example, “the height of the film surface” may refer to a height with respect to the concave structure surface 2002a, that is, a difference between a height of the concave structure surface 2002a and the height of the surface of the poly-Si layer 2005. The height measuring apparatus may include any general configuration regardless of an optical configuration or a contact configuration. A detailed description of the height measuring apparatus will be omitted.

When the wafer 200 processed in the polishing step S103 is loaded, the height measuring apparatus obtains the height distribution data of the surface of the poly-Si layer 2005 formed on the wafer 200 by measuring the height of the surface of the poly-Si layer 2005 formed on the wafer 200 at a plurality of locations including at least the center portion and peripheral portion of the wafer 200. Whether the height distribution of the surface of the poly-Si layer 2005 processed in the polishing step S103 is the distribution A or the distribution B may be seen by obtaining the height distribution data of the surface of the poly-Si layer 2005. After the height distribution data is obtained, the wafer 200 is unloaded from the height measuring apparatus.

The height distribution data obtained using the height measuring apparatus is transmitted to at least a top apparatus of the height measuring apparatus. The height distribution data may be transmitted to the substrate processing apparatus which performs the second silicon-containing layer forming step S105 to be described below through the top apparatus. Therefore, the top apparatus (also including the substrate processing apparatus when the height distribution data is transmitted to the substrate processing apparatus) may obtain the height distribution data from the height measuring apparatus.

[Second Silicon-Containing Layer Forming Step S105]

In the second silicon-containing layer forming step S105, a second silicon-containing layer formed of a chemical compound different from that of the poly-Si layer 2005 is formed on the polished poly-Si layer 2005. However, in the second silicon-containing layer forming step S105, when the second silicon-containing layer is formed, a process condition for correcting the variation of the height of the surface of the poly-Si layer 2005 on the wafer 200 is determined based on the height distribution data which is the measured result in the height measuring step S104. The second silicon-containing layer is formed on the poly-Si layer 2005 according to the determined process condition. As described below, the height of the surface of the laminated film including the poly-Si layer 2005 and the second silicon-containing layer formed on the poly-Si layer 2005 at the center portion of the wafer 200 is corrected to be substantially the same as the height of the surface of the laminated film at the peripheral portion thereof. In the specification of the present disclosure, “substantially the same heights” are not limited to completely the same heights, and the heights may be different from each other within a range that does not affect a subsequent process.

The second silicon-containing layer is formed using a substrate processing apparatus capable of performing film-forming processing according to the process condition determined based on the height distribution data. The wafer 200 unloaded from the height measuring apparatus is loaded into the substrate processing apparatus, and the second silicon-containing layer is formed. A configuration and processing of the substrate processing apparatus will be described below in detail.

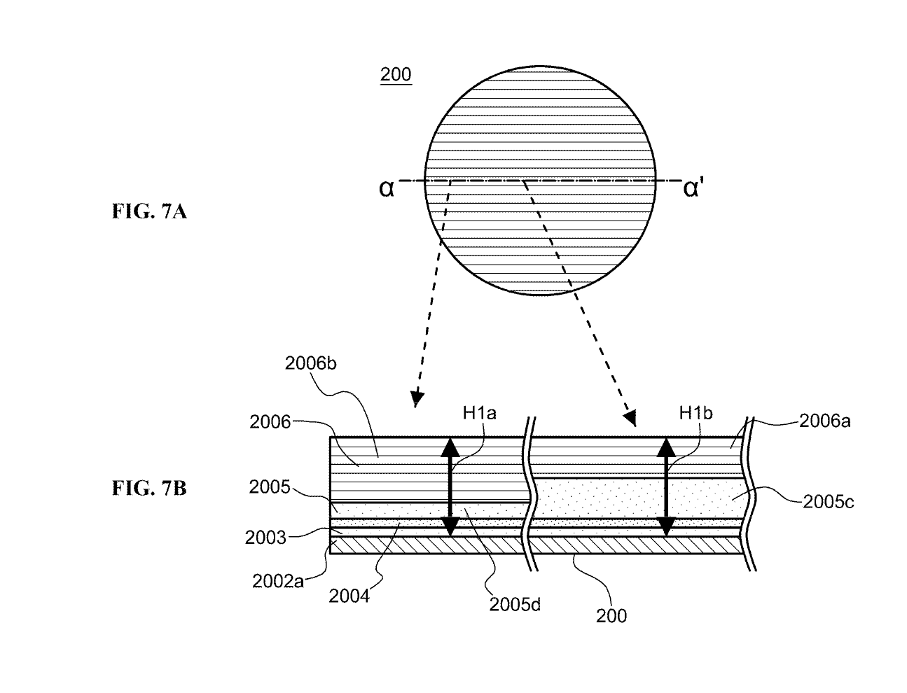

As illustrated in FIGS. 7A and 7B, for example, a second silicon-containing layer (hereinafter referred to as a “SiN layer”) 2006 including silicon nitride (SiN) serving as a chemical compound different from that of poly-Si constituting the poly-Si layer 2005 is formed on the poly-Si layer 2005 using the substrate processing apparatus. After the second silicon-containing layer 2006 is formed, the wafer 200 is unloaded from the substrate processing apparatus.

The SiN layer 2006 is harder than the poly-Si layer 2005 and is a film having an etching rate different from that of the poly-Si layer 2005. The SiN layer 2006 is used as a hard mask such as an etching stopper or a polishing stopper. When a damascene wiring is formed, the SiN layer 2006 may be used as a barrier insulating film. Since the SiN layer 2006 is used as the hard mask, the SiN layer 2006 is removed lastly after performing the patterning as will be described below.

When the SiN layer 2006 is formed, a process condition for forming the SiN layer 2006 is determined so that the variation of the height of the surface of the polished poly-Si layer 2005 is adjusted (tuned) based on the height distribution data obtained in the height measuring step S104. In the specification of the present disclosure, the adjustment (the tuning) refers to the formation of the SiN layer 2006 so that a difference between a height of the laminated film at the center portion of the poly-Si layer 2005 and the SiN layer 2006 and a height at the peripheral portion thereof is reduced. For example, the process condition is determined so that a thickness of the SiN layer 2006 at a portion at which the height of the surface of the poly-Si layer 2005 is small is increased and a thickness of the SiN layer 2006 at a portion at which the height of the surface of the poly-Si layer 2005 is large is decreased.

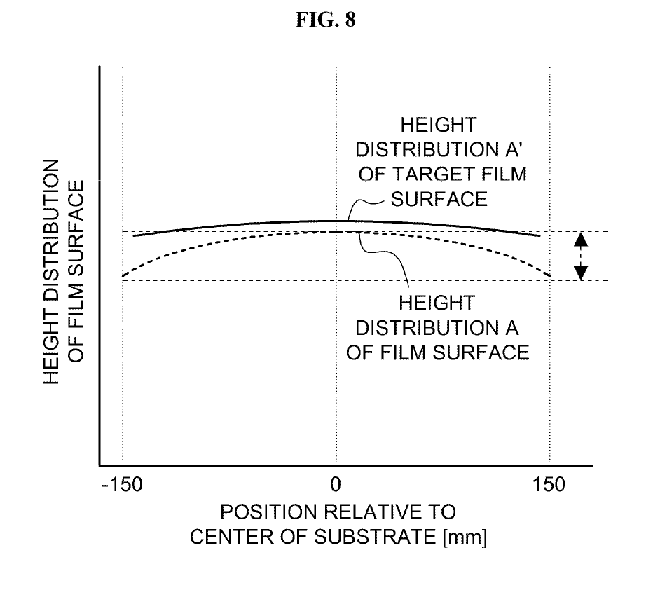

For example, as illustrated in FIG. 8, when the height distribution of the surface of the poly-Si layer 2005 is the distribution A, the process condition for forming the SiN layer 2006 is determined so that the height distribution of the SiN layer 2006 becomes a height distribution A′ of a target film surface by forming a peripheral portion of the SiN layer 2006 to be thick and a center portion thereof to be thin.

As illustrated in FIGS. 7A and 7B, the height of the surface of the SiN layer 2006 formed according to the process condition is substantially constant. More specifically, a height H1a of a surface of the SiN layer 2006b which is formed as a film at the peripheral portion of the wafer 200 is substantially the same as a height H1b of a surface of the SiN layer 2006a which is formed as a film at the center portion of the wafer 200. The “height” refers to a height with respect to the concave structure surface 2002a, that is, a difference between the height of the concave structure surface 2002a and the height of the surface of the SiN layer 2006.

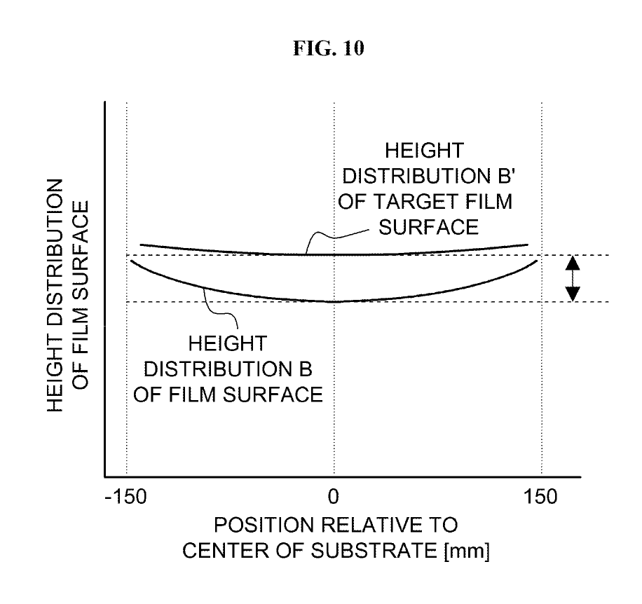

As illustrated in FIG. 10, when the height distribution of the surface of the poly-Si layer 2005 is the distribution B, the process condition for forming the SiN layer 2006 is determined so that the height distribution of the SiN layer 2006 becomes a height distribution B′ of the target film surface by forming the peripheral portion of the SiN layer 2006 to be thin and the center portion thereof to be thick.

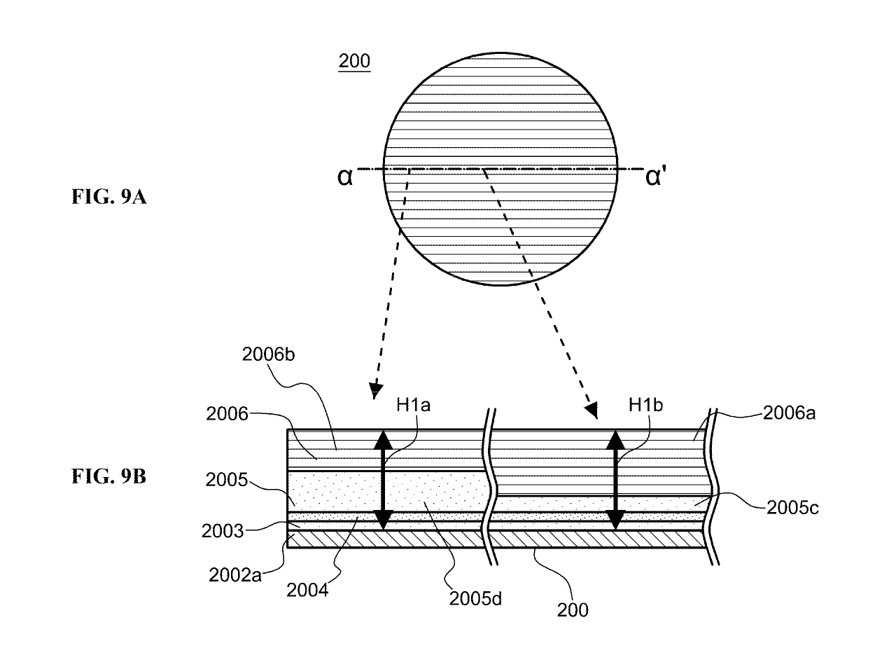

As illustrated in FIGS. 9A and 9B, the height of the surface of the SiN layer 2006 formed according to the process condition is substantially constant. More specifically, the height H1a of the surface of the SiN layer 2006b which is formed as a film at the peripheral portion of the wafer 200 is substantially the same as the height H1b of the surface of the SiN layer 2006a which is formed as a film at the center portion of the wafer 200.

As described above, in the second silicon-containing layer forming step S105, the variation of the height of the surface of the poly-Si layer 2005 polished by forming the SiN layer 2006 which functions as the hard mask is adjusted (tuned).

[Height Measuring Step S106]

After the second silicon-containing layer forming step S105 is performed, subsequently, the height measuring step S106 may be additionally performed. In the height measuring step S106, the height of the surface of the laminated film of the poly-Si layer 2005 and the SiN layer 2006 is measured. Specifically, it is determined whether the height of the surface of the laminated film is substantially constant, that is, whether the height distribution of the SiN layer 2006 is formed to become the height distribution of the target film surface, and thus whether the variation of the height of the surface of the poly-Si layer 2005 is adjusted (tuned). In the specification of the present disclosure, “substantially the same heights” are not limited to completely the same heights, and the heights may be different from each other within a range that does not affect the subsequent patterning step S109 and the like.

The height of the surface of the laminated film is measured using the height measuring apparatus. That is, the wafer 200 unloaded from the substrate processing apparatus is loaded into the height measuring apparatus, and the height of the surface of the laminated film is measured. The height measuring apparatus may include any general configuration regardless of an optical configuration or a contact configuration. In this specification, a detailed description thereof will be omitted.

When the wafer 200 processed in the second silicon-containing layer forming step S105 is loaded, the height measuring apparatus measures the height of the surface of the laminated film of the poly-Si layer 2005 and the SiN layer 2006 formed on the wafer 200 at a plurality of locations including at least the center portion and peripheral portion of the wafer 200. Whether the height of the surface of the laminated film of the poly-Si layer 2005 and the SiN layer 2006 is substantially constant may be seen by measuring the height at the plurality of locations. After the height is measured, the wafer 200 is unloaded from the height measuring apparatus. The data obtained by measuring the heights through the height measuring apparatus is transmitted to the top apparatus of the height measuring apparatus.

As a result of measuring of the height of the film surface, when the height distribution the surface of the laminated film formed on the wafer 200 is within a predetermined range, specifically, within the range that does not affect the subsequent patterning step S109 and the like, the patterning step S109 is performed next. When it is already known that the height distribution of the film surface is a predetermined distribution, the height measuring step S106 may be omitted.

[Patterning Step S109]

In the patterning step S109, the laminated film of the poly-Si layer 2005 and the SiN layer 2006 is patterned. Specifically, the laminated film is patterned by sequentially performing a coating process in which a resist film is formed by coating the surface of the laminated film with a resist material, an exposure process in which the resist film is exposed with a predetermined pattern, a developing process in which a photosensitive portion or a non-photosensitive portion of the exposed resist film is developed in order to remove a portion thereof, and an etching process in which the laminated film is etched by masking the laminated film using the resist film as a mask after the developing.

The patterning step S109 will be described below in detail through specific examples and comparative examples.

(2) Substrate Processing System

Next, a substrate processing system including a group of apparatuses which perform the above-described method of manufacturing the semiconductor device, that is, the first embodiment of the substrate processing system described herein will be described.

As described above, each of the gate insulating film forming step S101 to the patterning step S109 is performed using different apparatuses. Although these apparatuses may operate independently, these apparatuses may function as a single system by linking the respective apparatuses. Hereinafter, a single system including a group of these apparatus is referred to as “a substrate processing system.”

(Example of Configuration of Overall System)

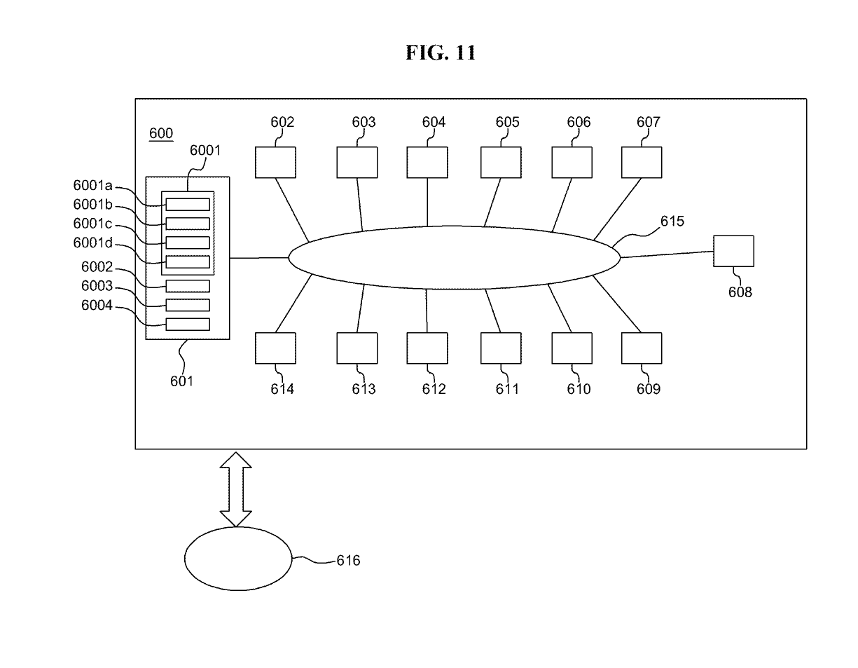

As illustrated in FIG. 11, a substrate processing system 600 includes a top apparatus 601 which controls the overall system. The substrate processing system 600 includes a gate insulating film forming apparatus 602 in which the gate insulating film forming step S101 is performed, a first silicon-containing layer forming apparatus 603 in which the first silicon-containing layer forming step S102 is performed, a CMP apparatus 604 in which the polishing step S103 is performed, a height measuring apparatus 605 in which the height measuring step S104 is performed, a substrate processing apparatus 606 in which the second silicon-containing layer forming step S105 is performed, a height measuring apparatus 607 in which the height measuring step S106 is performed, and a group of patterning apparatuses 608 through 614 in which the patterning step S109 is performed. The group of the patterning apparatuses 608 through 614 includes a coating apparatus 608 in which a coating process is performed, an exposure apparatus 609 in which an exposure process is performed, a developing apparatus 610 in which a developing process is performed, and etching apparatuses 611 through 614 in which an etching process is performed. The substrate processing system 600 includes a network line 615 for exchanging information between the respective apparatuses 601 through 614.

The substrate processing system 600 may be constituted by appropriately selecting the respective apparatuses 601 through 614. For example, apparatuses having a redundant function may be aggregated into a single apparatus. The processing of the substrate processing system 600 may not be managed in the substrate processing system 600, but may be managed using another system. When the processing of the substrate processing system 600 is managed using another system, the substrate processing system 600 may perform an information transmission with another system through a top network 616.

In the substrate processing system 600 of the above-described configuration, the top apparatus 601 includes a controller 6001 which controls an information transmission between the respective apparatuses 601 through 614.

The controller 6001 operates as a control unit (a control device) in the system, and is embodied as a computer including a central processing unit (CPU) 6001a, a random access memory (RAM) 6001b, a memory device 6001c and an input-and-output (I/O) port 6001d. The RAM 6001b, the memory device 6001c and the I/O port 6001d may exchange data with the CPU 6001a through an internal bus which is not illustrated. The memory device 6001c is embodied by, for example, a flash memory or a hard disk drive (HDD), and readably stores various type of programs (e.g., a control program controlling operations of the computer or an application program for performing a specific purpose). The RAM 6001b includes a memory area (a work area) in which a program or data read by the CPU 6001a is temporarily stored. For example, an I/O device 6002 such as a touch panel or an external memory device 6003 may be connected to the controller 6001. A transceiver 6004 may be installed in the controller 6001 and may transmit and receive information through another external apparatus of the substrate processing system 600 and a network.

The CPU 6001a of the controller 6001 reads and executes the control program from the memory device 6001c, and reads various type of application programs [e.g., a program for instructing the operating command to the substrate processing apparatus 606 and the like] from the memory device 6001c according to an input of a control command input from the I/O device 6002 and the like. The CPU 6001a controls an operation for transmitting information to the respective apparatuses 602 through 614 according to the content of the program.

The controller 6001 may be embodied by a dedicated computer, but the described technique is not limited thereto, and the controller 6001 may be embodied by, for example, a general-purpose computer. For example, the controller 6001 according to the present embodiment may be embodied by preparing the external memory device 6003 (e.g., a magnetic tape, a magnetic disk such as a flexible disk and a hard disk, an optical disc such as a compact disc (CD) or a digital versatile disc (DVD), a magneto-optical disc such as an MO and a semiconductor memory such as a Universal Serial Bus (USB) memory and a memory card) storing the above-described program and by installing the program in a general-purpose computer using the external memory device 6003. A method of supplying the program to the computer is also not limited to it being supplied through the external memory device 6003. For example, the program may be suppled using a communication line such as the Internet or a dedicated line without the external memory device 6003. The memory device 6001c or the external memory device 6003 is embodied as a non-transitory computer-readable recording medium. Hereinafter, these are also collectively simply called “a recording medium.” The term “recording medium” used in this specification refers to either or both of the memory device 6001c and the external memory device 6003. The term “program” used in this specification refers to either or both of the control program and the application program.

(Example of Processing in System)

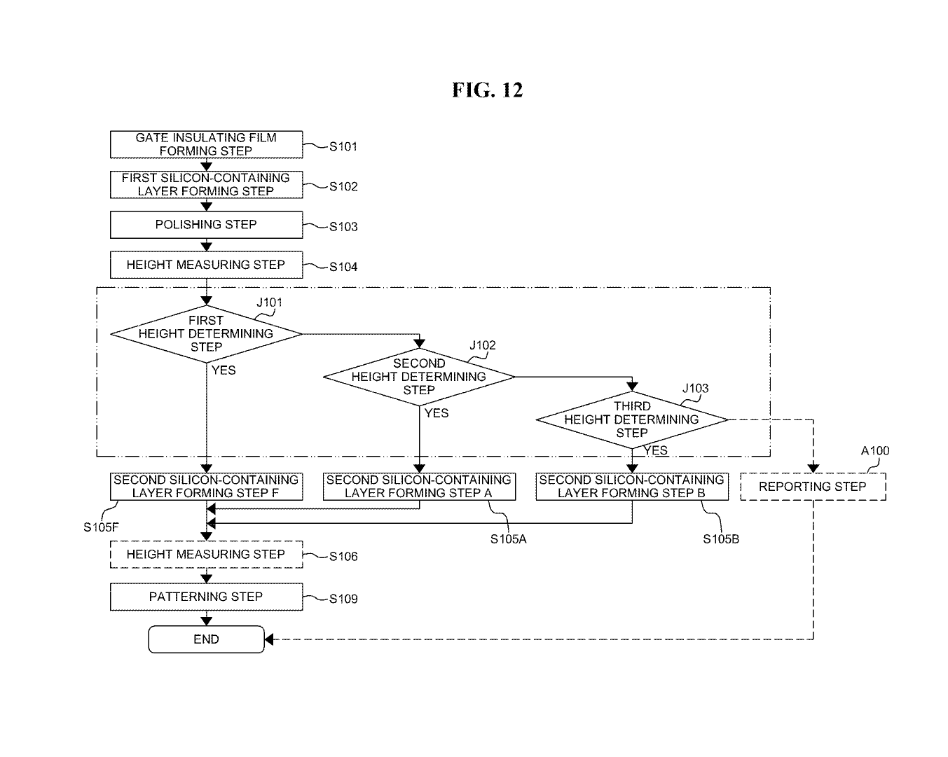

Next, exemplary processing when the top apparatus 601 controls processing performed in the substrate processing system 600, specifically, processing of the substrate processing apparatus 606 based on the data (the height distribution data of the film surface) received from the height measuring apparatus 605, will be described with reference to FIG. 12. The same reference numerals in the drawings are assigned to the same component as in the above-described steps [S101 to S104, S106 and S109 of FIG. 1] of the steps of the processing in the system and a detailed description thereof will be omitted.

The height distribution data of the film surface obtained by the height measuring apparatus 605 of the substrate processing system 600 by performing the height measuring step S104 is transmitted to the top apparatus 601. When the height distribution data of the film surface is received from the height measuring apparatus 605, the controller 6001 of the top apparatus 601 performs a height determining step J100 to be described below. The height determining step J100 includes a first height determining step J101, a second height determining step J102 and a third height determining step J103 according to the obtained content of the height distribution data of the film surface.

[First Height Determining Step J101]

In the first height determining step J101, determination of whether a height of the film surface is within a predetermined range, that is, whether an adjustment (a tuning) with respect to a variation of the height of the film surface is required, based on the obtained content of the height distribution data of the film surface is performed. For example, the determination may be performed by calculating a difference between a maximum value and a minimum value of the height of the surface of the poly-Si layer 2005 (indicated by a dashed line arrow in FIGS. 8 and 10) and comparing the calculated difference with a threshold value of the predetermined range based on the obtained height distribution data of the film surface. In the case in which it is determined that the difference is within a range of the threshold value and that the height of the film surface is within the predetermined range, the adjustment (the tuning) with respect to the variation of the height of the film surface is not required. The wafer 200 is transferred to the substrate processing apparatus 606, and the controller 6001 calculates data, which indicates a process condition (hereinafter referred to as “a process condition data”), and transmits the calculated process condition data to the substrate processing apparatus 606. Since the adjustment (the tuning) with respect to the variation of the height of the film surface is not required, the process condition data transmitted to the substrate processing apparatus 606 includes a process condition in which the substrate processing apparatus 606 does not adjust the height distribution of the SiN layer 2006 and forms the flat SiN layer 2006 on the surface of the wafer 200. The substrate processing apparatus 606 performs a second silicon-containing layer forming step S105F based on the received process condition data. When it is determined that the height of the film surface is not within the predetermined range, the controller 6001 subsequently performs the second height determining step J102.

[Second Height Determining Step J102]

In the second height determining step J102, when it is determined that the height of the film surface is not within the predetermined range, whether the height distribution corresponds to the distribution A is determined. For example, whether the height of the surface of the poly-Si layer 2005 at the center portion of the wafer 200 is greater than the height of the surface of the poly-Si layer 2005 at the peripheral portion thereof is determined based on the obtained height distribution data of the film surface. When it is determined that the height at the center portion is greater than the height at the peripheral portion and the height distribution of the surface of the poly-Si layer 2005 corresponds to the distribution A, the wafer 200 is transferred to the substrate processing apparatus 606, and the controller 6001 calculates a process condition data and transmits the calculated process condition data to the substrate processing apparatus 606. The process condition data transmitted to the substrate processing apparatus 606 includes a process condition in which the height distribution of the film surface becomes the height distribution A′ of the target film surface when the substrate processing apparatus 606 forms the SiN layer 2006 (see FIG. 8). The substrate processing apparatus 606 performs a second silicon-containing layer forming step S105A based on the process condition data in which the height of the surface of the SiN layer 2006 is substantially constant, that is, has the height distribution A′. When it is determined that the height distribution of the surface of the poly-Si layer 2005 does not correspond to the distribution A, the controller 6001 subsequently performs the third height determining step J103.

[Third Height Determining Step J103]

In the third height determining step J103, when it is determined that the height of the film surface is not within the predetermined range and the height distribution does not correspond to the distribution A, whether the height distribution corresponds to the distribution B is determined. For example, whether the height of the surface of the poly-Si layer 2005 at the peripheral portion of the wafer 200 is greater than the height of the surface of the poly-Si layer 2005 at the center portion thereof is determined based on the obtained height distribution data of the film surface. When it is determined that the height at the peripheral portion is greater than the height at the center portion and the height distribution of the surface of the poly-Si layer 2005 corresponds to the distribution B, the wafer 200 is transferred to the substrate processing apparatus 606, and the controller 6001 calculates a process condition data and transmits the calculated process condition data to the substrate processing apparatus 606. The process condition data transmitted to the substrate processing apparatus 606 includes a process condition in which the height distribution of the film surface becomes the height distribution B′ of the target film surface when the substrate processing apparatus 606 forms the SiN layer 2006 (see FIG. 10). The substrate processing apparatus 606 performs a second silicon-containing layer forming step S105B based on the process condition data in which the height of the surface of the SiN layer 2006 is substantially constant, that is, has the height distribution B′.

When it is determined that the height of the film surface is not within the predetermined range and the height distribution does not correspond to any one of the distribution A and the distribution B, the controller 6001 may output information which indicates that an adjustment is impossible to the I/O device 6002 or perform a reporting step A100 in which the information may be transmitted to the top network 616, and then the processing with respect to the wafer 200 may be completed.

[Height Determining Step J100]

As described above, in the height determining step J100 including the first height determining step J101, the second height determining step J102 and the third height determining step J103, process condition data for reducing the difference between the height of the laminated film of the poly-Si layer 2005 and the SiN layer 2006 at the center portion of the wafer 200 and the height at the peripheral portion thereof is calculated based on the height distribution data of the film surface. The substrate processing apparatus 606 may determine the process condition when forming the SiN layer 2006 by transmitting the process condition data calculated in the height determining step J100 to the substrate processing apparatus 606.

In the height determining step J100, the first height determining step J101, the second height determining step J102 and the third height determining step J103 are exemplified to be respectively performed, but the present embodiment is not limited thereto. For example, in the height determining step J100, the first height distribution determining step J101, the second height distribution determining step J102 and the third height distribution determining step J103 may be simultaneously performed on the height of the film at a predetermined location of the wafer 200.

In the present embodiment, the height determining step J100 is described to be performed by the controller 6001 of the top apparatus 601 as an example, but the present embodiment is not limited thereto. For example, the height determining step J100 may be performed by a controller (not illustrated) installed in the height measuring apparatus 605 other than the top apparatus 601. The controller (not illustrated) installed in the height measuring apparatus 605 may transmit the height distribution data of the film surface to at least one of the top apparatus 601 and the substrate processing apparatus 606 which performs a next step. For example, the height determining step J100 may be performed by a controller (not illustrated) installed in the substrate processing apparatus 606. However, the height determining step J100 is preferably performed by the controller 6001 of the top apparatus 601 in view of the following. The controller 6001 of the top apparatus 601 may have a specification of a high performance computer compared to a controller of another apparatus in the substrate processing system 600. Therefore, the controller 6001 of the top apparatus 601 may quickly perform the height determining step J100. When the controller 6001 of the top apparatus 601 which controls the overall system performs the height determining step J100, a transfer path of the wafer 200 which moves between the apparatuses 602 through 614 may be optimized according to the determination result in the height determining step J100, and as a result, manufacturing throughput of a FinFET may be improved. The usage of the respective apparatuses 602 through 614 or an analysis load in which the variation of the height distribution data of the film surface is analyzed may be reduced by the controller 6001 of the top apparatus 601 by performing the height determining step J100 and outputting the determination result in the height determining step J100 to the I/O device 6002 or by transmitting the determination result to the top network 616. The controller 6001 of the top apparatus 601 may easily determine, for example, maintenance times of the apparatuses 602 through 614 by outputting information such as the number of Ys (Yes's), the number of Ns (No's) and a ratio of N/Y to the I/O device 6002 or transmitting the information to the top network 616 in each of the first height determining step J101, the second height determining step J102 and the third height determining step J103.

(3) Configuration of Substrate Processing Apparatus

Next, in the substrate processing system 600 of the above-described configuration, a configuration of the substrate processing apparatus 606 which performs the second silicon-containing layer forming step S105 according to the process condition determined in the height determining step J100 will be described.

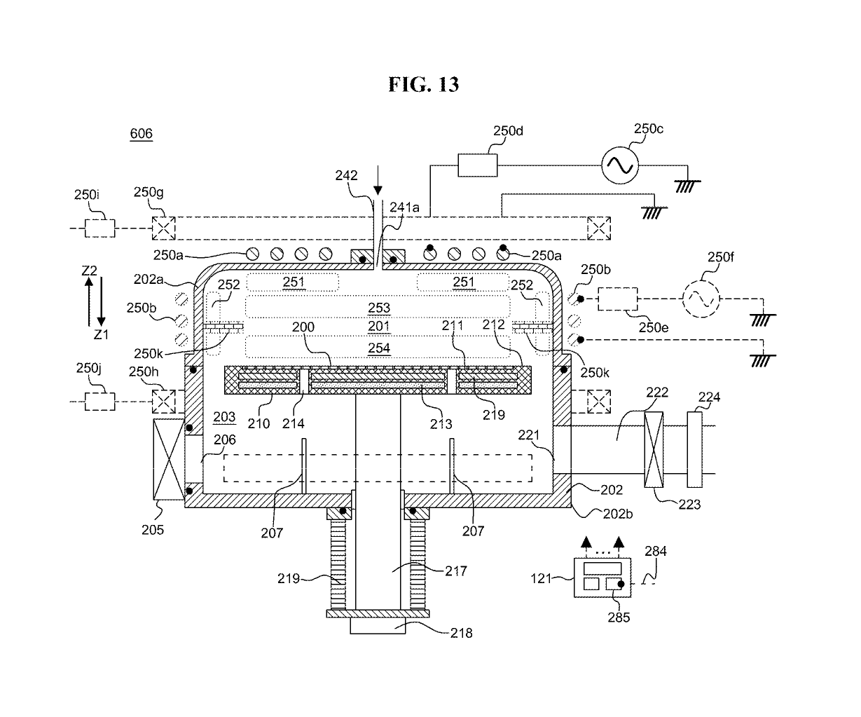

The substrate processing apparatus 606 is configured to form the SiN layer 2006 according to the process condition calculated based on the height distribution data of the film surface, and specifically, as illustrated in FIG. 13, is a single substrate processing apparatus.

(Process Container)

The substrate processing apparatus 606 includes a process container 202. The process container 202 includes, for example, an airtight container with a circular and flat cross section. The process container 202 includes an upper container 202a formed of a non-metallic material such as quartz or a ceramic and a lower container 202b formed of quartz or a metallic material such as aluminum (Al) or stainless steel (SUS). A processing space (a process chamber) 201 which processes a wafer such as a silicon wafer serving as a substrate is provided in an upper portion (an upper portion) in the process container 202 [a space above a substrate placement unit 212 to be described below], and a transfer space 203 under the processing space 201 is provided in a space which is surrounded by the lower container 202b.

A substrate loading and unloading port 206 is installed adjacent to a gate valve 205 on a side surface of the lower container 202b. The wafer 200 is loaded into the transfer space 203 through the substrate loading and unloading port 206. A plurality of lift pins 207 are installed at a bottom portion of the lower container 202b. The lower container 202b is at a ground potential (an earth electric potential).

(Substrate Placement Unit)

A substrate support (a susceptor) 210 which supports the wafer 200 is installed in the processing space 201. The substrate support 210 includes a placement surface 211 on which the wafer 200 is placed, a substrate placement unit 212 whose surface has the placement surface 211 and a heater 213 serving as a heating unit embedded in the substrate placement unit 212. A plurality of through-holes 214 through which the plurality of lift pins 207 pass are installed in the substrate placement unit 212 at positions corresponding to the plurality of lift pins 207.

The substrate placement unit 212 is supported by a shaft 217. The shaft 217 passes through a bottom portion of the process container 202 and is connected to a lifting mechanism 218 outside the process container 202. The substrate placement unit 212 may lift the wafer 200 placed on the placement surface 211 by lifting the shaft 217 and the substrate placement unit 212 by operating the lifting mechanism 218. A bellows 219 covers a vicinity of a lower end of the shaft 217. The processing space 201 is air-tightly maintained by the bellows 219.

When the wafer 200 is transferred, the substrate placement unit 212 is lowered. Specifically, the placement surface 211 is lowered to a position (a wafer transfer position) corresponding to the substrate loading and unloading port 206. When the wafer 200 is processed, as illustrated in FIG. 13, the substrate placement unit 212 is lifted, and is specifically lifted to a position (a wafer processing position) at which the wafer 200 is positioned in the processing space 201. Specifically, when the substrate placement unit 212 is lowered to the wafer transfer position, upper ends of the lift pins 207 protrude from an upper surface of the placement surface 211, and the lift pins 207 support the wafer 200 from below. When the substrate placement unit 212 is lifted to the wafer processing position, the lift pins 207 are buried under the upper surface of the placement surface 211 and the placement surface 211 supports the wafer 200 from below. Since the lift pins 207 are directly in contact with the wafer 200, the lift pins 207 are preferably formed of a material such as quartz or alumina. A lifting mechanism (not illustrated) may be installed in the lift pins 207 to move the lift pins 207.

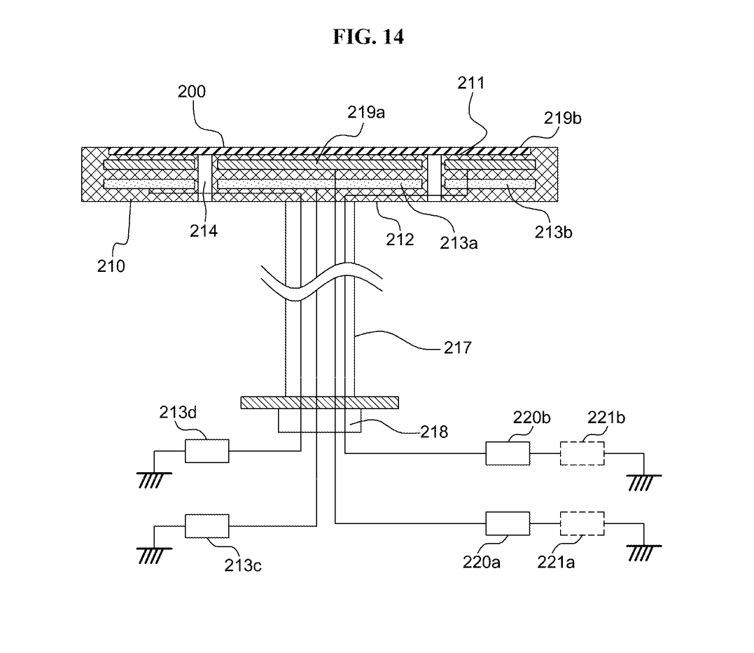

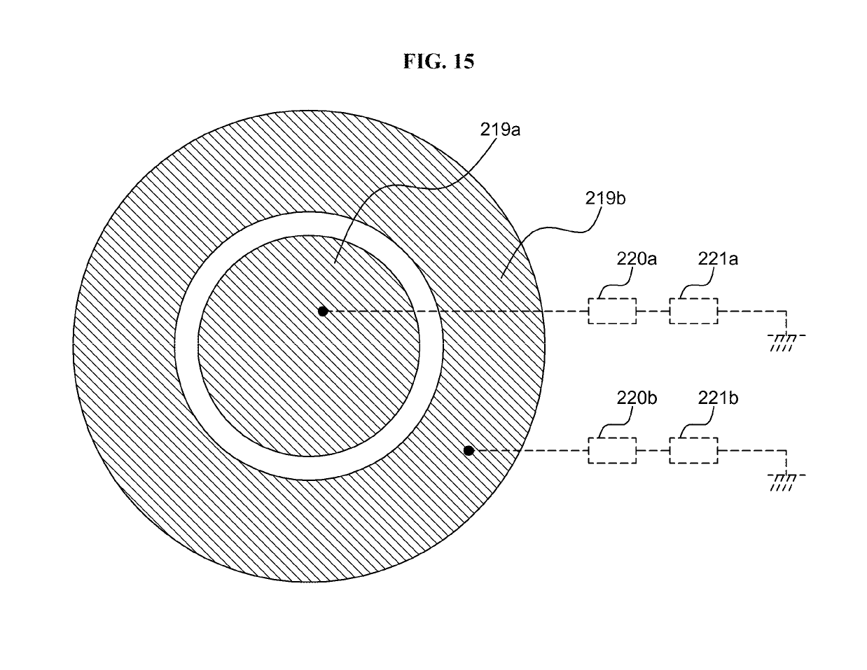

As illustrated in FIG. 14, a first bias electrode 219a and a second bias electrode 219b included in a bias adjuster 219 are installed in the substrate placement unit 212. The first bias electrode 219a is connected to a first impedance adjuster 220a, and the second bias electrode 219b is connected to a second impedance adjuster 220b. An electric potential of each of the first bias electrode 219a and the second bias electrode 219b may be adjusted. As illustrated in FIG. 15, the first bias electrode 219a and the second bias electrode 219b are concentrically disposed, and each of an electric potential applied to the center portion of the wafer 200 and an electric potential applied to the peripheral portion thereof may be adjusted. A first impedance adjusting power source 221a may be connected to the first impedance adjuster 220a, and a second impedance adjusting power source 221b may be connected to the second impedance adjuster 220b. By installing the first impedance adjusting power source 221a, an adjustment range of the electric potential of the first bias electrode 219a may be increased and an adjustment range of an amount of an active species introduced into the center portion of the wafer 200 may be increased. By installing the second impedance adjusting power source 221b, an adjustment range of the electric potential of the second bias electrode 219b may be increased and an adjustment range of an amount of an active species introduced into the peripheral portion of the wafer 200 may be increased. For example, when the active species is at a positive electric potential, the electric potential of the first bias electrode 219a becomes a negative electric potential, the electric potential of the second bias electrode 219b is greater than the electric potential of the first bias electrode 219a, and thus an amount of the active species supplied to the center portion of the wafer 200 may be greater than an amount of the active species supplied to the peripheral portion thereof. Even when the electric potential of the active species generated in the process chamber 201 is close to a neutral electric potential, the amount of the active species introduced into the wafer 200 may be adjusted by controlling at least one of the first impedance adjusting power source 221a and the second impedance adjusting power source 221b.

The substrate placement unit 212 includes the heater 213 serving as a heating unit. The heater 213 may include a first heater 213a and a second heater 213b which are installed in respective zones illustrated in FIG. 14. The first heater 213a may be installed to face the first bias electrode 219a, and the second heater 213b may be installed to face the second bias electrode 219b. The first heater 213a is connected to a first heater power source 213c, and the second heater 213b is connected to a second heater power source 213d. An amount of power supplied to the first heater 213a and the second heater 213b may be adjusted.

(Activation Unit)

As illustrated in FIG. 13, a first coil 250a serving as a first activation unit (an upper activation unit) is installed above the upper container 202a. A first high-frequency power source 250c is connected to the first coil 250a through a first matching box 250d. A gas supplied into the process chamber 201 may be excited in the process chamber 201 to generate plasma by supplying high-frequency power to the first coil 250a. Specifically, the plasma is generated in a space [a first plasma generation region 251] which is an upper portion of the process chamber 201 and faces the wafer 200. The plasma may also be generated in a space facing the substrate placement unit 212 as well as the above-described space.

A second coil 250b serving as a second activation unit (a lateral activation unit) may be installed outside a side surface of the upper container 202a. A second high-frequency power source 250f is connected to the second coil 250b through a second matching box 250e. A gas supplied into the process chamber 201 may be excited in the process chamber 201 to generate plasma by supplying high-frequency power to the second coil 250b. Specifically, the plasma is generated in a space [a second plasma generation region 252] more outward than the space facing the wafer 200, which is a side surface of the process chamber 201. The plasma may be generated in a space more outward than the space facing the substrate placement unit 212 as well as the space.

According to the present embodiment, the matching boxes 250d and 250e and the high-frequency power 250c and 250f are installed in each of the first coil 250a and the second coil 250b, but the present embodiment is not limited thereto. For example, the first coil 250a and the second coil 250b may use a common matching box and the first coil 250a and the second coil 250b may use common high-frequency power.

[Magnetic Field Generating Unit]

A first electromagnet [an upper electromagnet 250g] serving as a first magnetic field generating unit may be installed above the upper container 202a. A first electromagnet power source 250i which supplies power to the first electromagnet 250g is connected to the first electromagnet 250g. The first electromagnet 250g may have a ring shape and generate a magnetic field in a direction of “Z1” or “Z2” illustrated in FIG. 11. The direction of the magnetic field is determined by a direction of current supplied from the first electromagnet power source 250i to the first electromagnet 250g.

A second electromagnet 250h (a side electromagnet) serving as a second magnetic field generating unit may be installed lower than the wafer processing position and outside the side surface of the process container 202. A second electromagnet power source 250j which supplies power to the second electromagnet 250h is connected to the second electromagnet 250h. The second electromagnet 250h may have a ring shape and generate a magnetic field in the direction of “Z1” or “Z2” illustrated in FIG. 11. The direction of the magnetic field is determined by a direction of current supplied from the second electromagnet power source 250j to the second electromagnet 250h.

According to the configuration, the plasma formed in the first plasma generation region 251 may be moved (diffused) to a third plasma generation region 253 or a fourth plasma generation region 254 by forming a magnetic field in the Z1 direction using any one of the first electromagnet 250g and the second electromagnet 250h. In the third plasma generation region 253, a degree of activity of the active species generated at a position facing the center portion of the wafer 200 is greater than a degree of activity of the active species generated at a position facing the peripheral portion of the wafer 200. This is because a gas is supplied into the center portion of the wafer 200. In the fourth plasma generation region 254, the degree of activity of the active species generated at the position facing the peripheral portion of the wafer 200 is greater than the degree of activity of the active species generated at the position facing the center portion of the wafer 200. This is because gas molecules gather in the peripheral portion of the wafer 200 due to an exhaust path formed in the peripheral portion of the substrate support 210. The position of the plasma may be controlled by the power supplied to the first electromagnet 250g and the second electromagnet 250h and may further approach the wafer 200 by increasing the power. The plasma may also approach the wafer 200 by forming the magnetic field in the Z1 direction using both of the first electromagnet 250g and the second electromagnet 250h. The plasma formed in the first plasma generation region 251 may be suppressed from being diffused toward the wafer 200 by forming the magnetic field in the Z2 direction. Therefore, energy of the active species supplied to the wafer 200 may be reduced. A direction of the magnetic field formed by the first electromagnet 250g may differ from a direction of the magnetic field formed by the second electromagnet 250h.

An electromagnetic wave shielding plate 250k may be installed in the processing space 201 between the first electromagnet 250g and the second electromagnet 250h. The electromagnetic wave shielding plate 250k isolates the magnetic field formed by the first electromagnet 250g from the magnetic field formed by the second electromagnet 250h. When the magnetic field is adjusted by adjusting a height at which the electromagnetic wave shielding plate 250k is installed, processing uniformity in the surface of the wafer 200 may be easily adjusted. A height of the electromagnetic wave shielding plate 250k may be adjusted by an electromagnetic wave shielding plate lifting mechanism (not illustrated).

(Exhaust System)

An exhaust port 221 serving as an exhaust unit which exhausts an atmosphere in the processing space 201 is installed on an inner wall of the transfer space 203 [the lower container 202b]. An exhaust pipe 222 is connected to the exhaust port 221. A pressure regulator 223 such as an auto pressure controller (APC) which controls an inner pressure of the processing space 201 to a predetermined pressure and a vacuum pump 224 are sequentially connected to the exhaust pipe 222. An exhaust system (an exhaust line) includes the exhaust port 221, the exhaust pipe 222 and the pressure regulator 223. The exhaust system (the exhaust line) may further include the vacuum pump 224.

(Gas Inlet)

A gas inlet 241a for supplying various types of gases into the processing space 201 is installed at an upper portion of the upper container 202a. A common gas supply pipe 242 is connected to the gas inlet 241a.

(Gas Supply Unit)

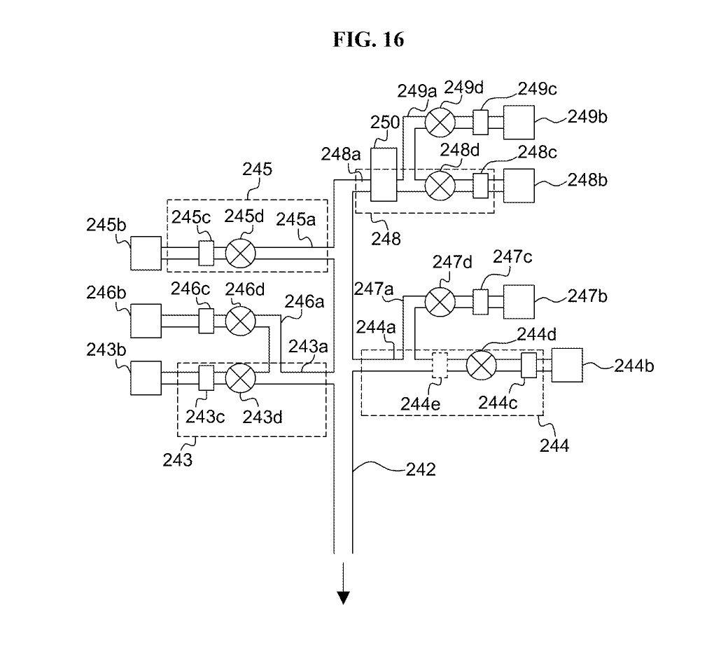

As illustrated in FIG. 16, a first gas supply pipe 243a, a second gas supply pipe 244a, a third gas supply pipe 245a and a cleaning gas supply pipe 248a are connected to the common gas supply pipe 242.

A first-element-containing gas (a first process gas) is mainly supplied through a first gas supply unit 243 including the first gas supply pipe 243a and a second-element-containing gas (a second process gas) is mainly supplied through a second gas supply unit 244 including the second gas supply pipe 244a. A purge gas is mainly supplied through a third gas supply unit 245 including the third gas supply pipe 245a, and a cleaning gas is mainly supplied through a cleaning gas supply unit 248 including the cleaning gas supply pipe 248a. A process gas supply unit which supplies a process gas includes at least one of the first gas supply unit 243 and the second gas supply unit 244, and the process gas includes at least one of the first process gas and the second process gas.

(First Gas Supply Unit)

A first gas supply source 243b, a mass flow controller (MFC) 243c serving as a flow rate controller (a flow rate control unit) and a valve 243d serving as an opening and closing valve are sequentially installed in the first gas supply pipe 243a from an upstream side to a downstream side. The first-element-containing gas (the first process gas) is supplied from the first gas supply source 243b and is supplied into the processing space 201 through the MFC 243c, the valve 243d, the first gas supply pipe 243a and the common gas supply pipe 242.

The first process gas is a source gas, that is, one of the process gases. For example, a first element contained in the first process gas is silicon (Si). That is, the first process gas includes, for example, a silicon-containing gas. For example, disilane (Si₂H₆) gas may be used as a silicon-containing gas. In addition to disilane (Si₂H₆) gas, a gas such as tetraethyl orthosilicate (Si(OC₂H₅)₄ abbreviated to TEOS) gas, bis(tertiary-butylamino)silane (SiH₂(NH(C₄H₉))₂ abbreviated to BTBAS) gas, tetrakis(dimethylamino)silane (Si[N(CH₆)₂]₄ abbreviated to 4DMAS) gas, bis(diethylamino)silane (Si[N(C₂H₅)₂]₂H₂, abbreviated to 2DEAS) gas, BTBAS gas, hexamethyldisilazane (C₆H₁₉NSi₂ abbreviated to HMDS) gas, trisilylamine ((SiH₆)₃N abbreviated to TSA) gas and hexachlorodisilane (Si₂Cl₆ abbreviated to HCDS) gas may be used as the silicon-containing gas. A first process gas source may be a solid, a liquid or a gas at room temperature and normal pressure. When the first process gas source is liquid at room temperature and normal pressure, a vaporizer (not illustrated) may be installed between the first gas supply source 243b and the MFC 243c. In the present embodiment, the first process gas source serving as a gas will be described.

A downstream end of a first inert gas supply pipe 246a is connected to a downstream side of the valve 243d of the first gas supply pipe 243a. An inert gas supply source 246b, an MFC 246c and a valve 246d serving as an opening and closing valve are sequentially installed in the first inert gas supply pipe 246a from an upstream side to a downstream side. An inert gas is supplied from the inert gas supply source 246b and is supplied into the processing space 201 through the MFC 246c, the valve 246d, the first inert gas supply pipe 246a, the first gas supply pipe 243a and the common gas supply pipe 242. The inert gas serves as a carrier gas or a dilution gas of the first process gas.

In the present embodiment, the inert gas includes, for example, helium (He) gas. In addition to He gas, rare gases such as neon (Ne) gas and argon (Ar) gas may be used as the inert gas. The inert gas may be a gas which does not easily react with the process gas, the wafer 200, a film-forming film and the like. For example, nitrogen (N₂) gas may be used as the inert gas.

The first gas supply unit 243 (referred to as a “silicon-containing gas supply unit”) includes the first gas supply pipe 243a, the MFC 243c and the valve 243d. A first inert gas supply unit includes the first inert gas supply pipe 246a, the MFC 246c and the valve 246d. The first inert gas supply unit may further include the inert gas supply source 246b and the first gas supply pipe 243a. The first gas supply unit 243 may further include the first gas supply source 243b and the first inert gas supply unit.

(Second Gas Supply Unit)

A second gas supply source 244b, an MFC 244c and a valve 244d serving as an opening and closing valve are sequentially installed in the second gas supply pipe 244a from an upstream side to a downstream side. A second-element-containing gas (the second process gas) is supplied from the second gas supply source 244b and is supplied into the processing space 201 through the MFC 244c, the valve 244d, the second gas supply pipe 244a and the common gas supply pipe 242.

The second process gas includes other process gases. The second process gas may be regarded as a reaction gas or a modifying gas. The second process gas contains a second element different from the first element. The second element is, for example, any one of nitrogen (N), oxygen (O), carbon (C) and hydrogen (H). In the present embodiment, a nitrogen-containing gas, which is a nitriding source of silicon, is used as a second process gas. Specifically, ammonia (NH₃) gas is used as the second process gas. A gas containing two or more of the elements may be used as the second process gas.

A downstream end of a second inert gas supply pipe 247a is connected to a downstream side of the valve 244d of the second gas supply pipe 244a. An inert gas supply source 247b, an MFC 247c and a valve 247d serving as an opening and closing valve are sequentially installed in the second inert gas supply pipe 247a from an upstream side to a downstream side. An inert gas is supplied from the inert gas supply source 247b and is supplied into the processing space 201 through the MFC 247c, the valve 247d, the second inert gas supply pipe 247a, the second gas supply pipe 244a and the common gas supply pipe 242. The inert gas serves as a carrier gas or a dilution gas of the second process gas. The inert gas may be the same as the inert gas supplied by the first inert gas supply unit.

The second gas supply unit 244 includes the second gas supply pipe 244a, the MFC 244c and the valve 244d. The second gas supply unit 244 may further include a remote plasma unit (RPU) 244e serving as an activation unit. The RPU 244e may activate the second process gas. A second inert gas supply unit includes the second inert gas supply pipe 247a, the MFC 247c and the valve 247d. The second inert gas supply unit may further include the inert gas supply source 247b and the second gas supply pipe 244a. The second gas supply unit 244 may further include the second gas supply source 244b and the second inert gas supply unit.

(Third Gas Supply Unit)

A third gas supply source 245b, an MFC 245c and a valve 245d serving as an opening and closing valve are sequentially installed in the third gas supply pipe 245a from an upstream side to a downstream side. An inert gas serving as a purge gas is supplied from the third gas supply source 245b and is supplied into the processing space 201 through the MFC 245c, the valve 245d, the third gas supply pipe 245a and the common gas supply pipe 242.

In the present embodiment, the inert gas includes, for example nitrogen (N₂) gas. In addition to N₂ gas, rare gases such as helium (He) gas, neon (Ne) gas and argon (Ar) gas may be used as an inert gas.

The third gas supply unit 245 (referred to as a “purge gas supply unit”) includes the third gas supply pipe 245a, the MFC 245c and the valve 245d.

(Cleaning Gas Supply Unit)

A cleaning gas source 248b, an MFC 248c, a valve 248d and a RPU 250 are sequentially installed in a cleaning gas supply pipe 243a from an upstream side to a downstream side. A cleaning gas is supplied from the cleaning gas source 248b and is supplied into the processing space 201 through the MFC 248c, the valve 248d, the RPU 250, the cleaning gas supply pipe 248a and the common gas supply pipe 242.

In the cleaning step, the cleaning gas serves as a cleaning gas which removes a material such as a by-product adhered to the processing space 201. In the present embodiment, the cleaning gas includes, for example, nitrogen trifluoride (NF₃) gas. For example, a gas such as hydrogen fluoride (HF) gas, chlorine trifluoride (ClF₃) gas, fluorine (F₂) gas and a combination thereof may be used as the cleaning gas.

A downstream end of a fourth inert gas supply pipe 249a is connected to a downstream side of the valve 248d of the cleaning gas supply pipe 248a. The fourth inert gas supply source 249b, the MFC 249c and the valve 249d are sequentially installed in the fourth inert gas supply pipe 249a from an upstream side to a downstream side. An inert gas is supplied from the fourth inert gas supply source 249b and is supplied into the processing space 201 through the MFC 249c, the valve 249d, the cleaning gas supply pipe 248a and the common gas supply pipe 242. The inert gas serves as a carrier gas or dilution gas of the cleaning gas. The inert gas may be the same as the inert gas supplied by the first inert gas supply unit or the second inert gas supply unit.

The cleaning gas supply unit 248 includes the cleaning gas supply pipe 248a, the MFC 248c and the valve 248d. The cleaning gas supply unit 248 may further include the cleaning gas source 248b, the fourth inert gas supply pipe 249a and the RPU 250.

Each of the above-described gas supply units 243, 244, 245 and 248 includes an MFC serving as a flow rate control unit. However, a flow rate control unit such as a needle valve or an orifice having high responsiveness with respect to the gas flow may be used. For example, although an MFC may not be responsive when a width of a gas pulse is on the order of milliseconds, a needle valve or an orifice may be responsive to the gas pulse of a millisecond or less by adding a high-speed ON/OFF valve.

(Control Unit)

As illustrated in FIG. 13, the substrate processing apparatus 606 includes a controller 121 serving as a control unit (a control device) which controls operations of the respective units of the substrate processing apparatus 606.

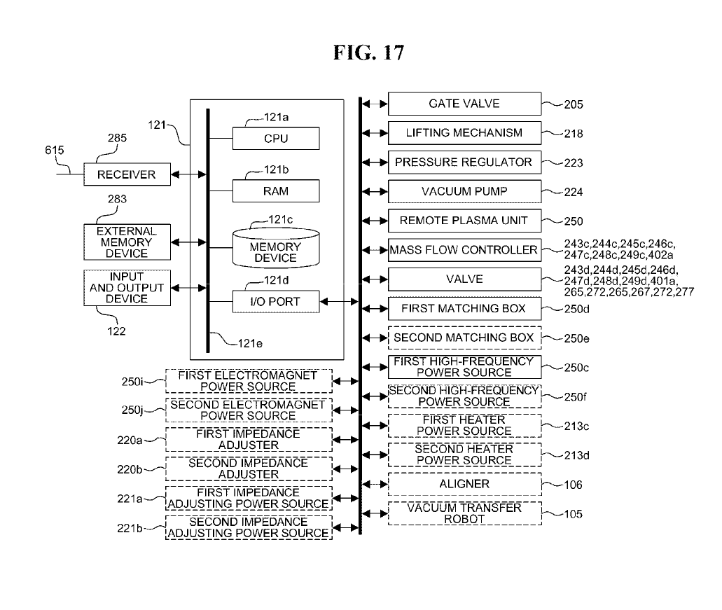

As illustrated in FIG. 17, the controller 121 is embodied as a computer including a CPU 121a, a RAM 121b, a memory device 121c and an I/O port 121d. The RAM 121b, the memory device 121c and the I/O port 121d may exchange data with the CPU 121a through an internal bus 121e. For example, an I/O device 122 such as a touch panel or an external memory device 283 may be connected to the controller 121. A receiver 285 connected through the top apparatus 601 and the network 615 is installed. The receiver 285 may receive information on another apparatus from the top apparatus 601. However, the receiver 285 may directly receive the information from another apparatus without the top apparatus 601. The information on another apparatus may be input through the I/O device 122 and stored in the external memory device 283.

The memory device 121c of the controller 121 having the above-described configuration is embodied as, for example, a flash memory or a HDD. A control program controlling the operations of the substrate processing apparatus 606 or a program recipe describing sequences, conditions or the like in each step performed as the second silicon-containing layer forming step S105 by the substrate processing apparatus 606 is readably stored in the memory device 121c. The process recipe which is a combination causes the controller 121 to execute each sequence in steps to be described below, in order to obtain a predetermined result and functions as a program. Hereinafter, the program recipe, the control program, or the like may be simply collectively referred to as a program.

The RAM 121b is configured as a memory area (a work area) in which a program or data read by the CPU 121a is temporarily stored.

The components such as the gate valve 205, the lifting mechanism 218, the pressure regulator 223, the vacuum pump 224, the RPU 250, the MFCs 243c, 244c, 245c, 246c, 247c, 248c and 249c, the valves 243d, 244d, 245d, 246d, 247d, 248d and 249d, the first matching box 250d, the second matching box 250e, the first high-frequency power source 250c, the second high-frequency power source 250f, the first impedance adjuster 220a, the second impedance adjuster 220b, the first impedance adjusting power source 221a, the second impedance adjusting power source 221b, the first electromagnet power source 250i, the second electromagnet power source 250j, the first heater power source 213c and the second heater power source 213d are connected to the I/O port 121d.

The CPU 121a reads and executes the control program from the memory device 121c and reads the process recipe from the memory device 121c according to an input of a control command from the I/O device 122. The CPU 121a may control opening and closing operations of the gate valve 205, a lifting operation of the lifting mechanism 218, a pressure regulating operation by the pressure regulator 223, an on-off control of the vacuum pump 224, a gas excitement operation of the RPU 250, flow rate regulating operations of the MFCs 243c, 244c, 245c, 246c, 247c, 248c and 249c, an on-off control of a gas of the valves 243d, 244d, 245d, 246d, 247d, 248d and 249d, a matching control of the first matching box 250d and the second matching box 250e, an on-off control of the first high-frequency power source 250c and the second high-frequency power source 250f, impedance regulating operations by the first impedance adjuster 220a and the second impedance adjuster 220b, an on-off control of the first impedance adjusting power source 221a and the second impedance adjusting power source 221b, a power control for the first electromagnet power source 250i and the second electromagnet power source 250j, a power control for the first heater power source 213c and the second heater power source 213d and the like according to the content of the read process recipe.

The controller 121 may be embodied by a dedicated computer, but the present embodiment is not limited thereto, and the controller 121 may be embodied by a general-purpose computer. For example, the controller 121 according to the present embodiment may be embodied by preparing the external memory device 283 (e.g., a magnetic tape, a magnetic disk such as a flexible disk and a hard disk, an optical disc such as a CD or a DVD, a magneto-optical disc such as an MO and a semiconductor memory such as a USB memory and a memory card) recording the above-described program and then installing the program in the general-purpose computer using the external memory device 283. A method of supplying the program to the computer is not limited to supplying the program through the external memory device 283. For example, a communication line such as the Internet or a dedicated line may be used to supply the program without the external memory device 283. The memory device 121c or the external memory device 283 is embodied as a non-transitory computer-readable recording medium. Hereinafter, these are also collectively simply called a “recording medium.” When the term “recording medium” is used in this specification, it refers to either or both of the memory device 121c and the external memory device 283. When the term “program” is used in this specification, it refers to either or both of the program recipe and the control program.

(4) Exemplary Processing of Substrate Processing Apparatus

Next, a sequence of exemplary processing of the substrate processing apparatus 606 of the above-described configuration, that is, a sequence when the SiN layer 2006 is formed by the substrate processing apparatus 606 performing the second silicon-containing layer forming step S105, will be described.

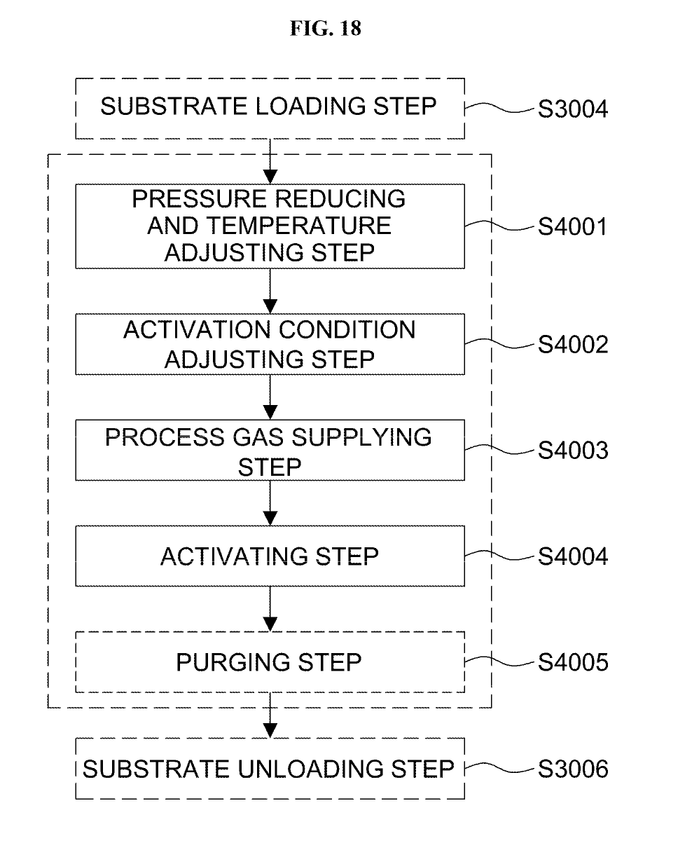

In the height measuring step S104, when the wafer 200 in which the height distribution of the surface of the poly-Si layer 2005 is measured is loaded and process condition data required in the height determining step J100 is received, the substrate processing apparatus 606 performs the second silicon-containing layer forming step S105. Specifically, as illustrated in FIG. 18, the substrate processing apparatus 606 forms the SiN layer 2006 on the poly-Si layer 2005 by sequentially performing a substrate loading step S3004, a pressure reducing and temperature adjusting step S4001, an activation condition adjusting step S4002, a process gas supplying step S4003, an activation step S4004, a purging step S4005 and a substrate unloading step S3006 according to the received process condition data. Hereinafter, the respective steps S3004, S4001 to S4005 and S3006 will be described.

In the following description, operations of the respective units constituting the substrate processing apparatus are controlled by the controller 121.

[Substrate Loading Step S3004]

When a height distribution of a surface of the poly-Si layer 2005 is measured in the height measuring step S104, the wafer 200 is loaded into the transfer space 203 of the substrate processing apparatus 606. Specifically, the substrate support 210 is lowered by the lifting mechanism 218 and thus the lift pins 207 protrude from the through-holes 214 toward the upper surface of the substrate support 210. After an inner pressure of the processing space 201 is adjusted to a predetermined pressure, the gate valve 205 is opened and the wafer 200 is placed on the lift pins 207 through the gate valve 205. In the present embodiment, the predetermined pressure refers to, for example, a pressure greater than or equal to an inner pressure of a vacuum transfer chamber (not illustrated) which communicates with the processing space 201 through the gate valve 205. After the wafer 200 is placed onto the lift pins 207, the substrate support 210 is lifted to a predetermined position by the lifting mechanism 218, and thus the wafer 200 is placed from the lift pins 207 onto the substrate support 210.

[Pressure Reducing and the Temperature Adjusting Step S4001]

After the wafer 200 is transferred onto the substrate support 210, the processing space 201 is exhausted through the exhaust pipe 222 so that the inner pressure of the processing space 201 becomes the predetermined pressure (the vacuum level). In this case, a degree of a valve opening of an APC valve serving as the pressure regulator 223 is fed back and controlled based on a pressure value measured by a pressure sensor (not illustrated). When the processing space 201 is exhausted, first, the processing space 201 may be exhausted to a degree of vacuum that it can immediately reach and then may be exhausted to a predetermined vacuum level. After the wafer 200 is transferred onto the substrate support 210, the heater 213 heats the substrate support 210. When the heater 213 heats the substrate support 210, power supplied to the heater 213 is fed back and controlled based on a temperature value detected by a temperature sensor (not illustrated) so that a temperature in the processing space 201 becomes a predetermined temperature. After the temperature change of the wafer 200 or the substrate support 210 is removed, a temperature of the wafer 200 or the substrate support 210 is maintained for a predetermined time. While the temperature is maintained, impurities such as a gas emitted from residual material or residual moisture in the process chamber 201 may be removed by purging by vacuum exhaustion or purging by supplying N₂ gas. Preparation before the film-forming process is now completed.

When the substrate support 210 is heated, a temperature of the first heater 213a and the second heater 213b may be adjusted (tuned) based on the received process condition data. A temperature at the center portion of the wafer 200 may differ from a temperature at the peripheral portion thereof by adjusting (tuning) the temperature of the first heater 213a and the second heater 213b, and subsequent processes performed at the center portion of the wafer 200 may differ from those performed at the peripheral portion thereof.

[Activation Condition Adjusting Step S4002]

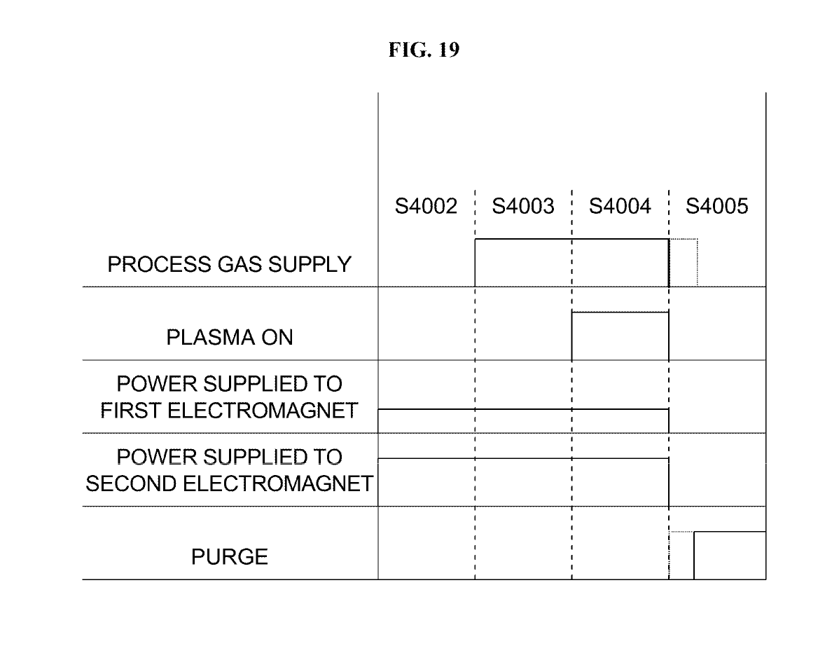

When the preparation before performing the film-forming process is completed, next, at least one of the following adjustments A to C is performed based on the received process condition data. FIG. 19 illustrates an example in which the adjustment A is performed.

Adjustment A: Adjusting Magnetic Field

After the preparation before performing the film-forming process is completed, predetermined power is supplied from the first electromagnet power source 250i and the second electromagnet power source 250j to the first electromagnet 250g and the second electromagnet 250h, respectively, and thus a predetermined magnetic field is formed in the processing space 201. For example, the magnetic field is formed in the processing space 201 in the direction of “Z1” or “Z2.” Characteristics such as magnetic field strengths and magnetic flux densities above the center portion and the peripheral portion of the wafer 200 are appropriately adjusted (tuned) based on the received process condition data. Specifically, the characteristics such as the magnetic field strengths and the magnetic flux densities may be adjusted (tuned) by appropriately controlling power supplied from the first electromagnet power source 250i to the first electromagnet 250g and power supplied from the second electromagnet power source 250j to the second electromagnet 250h. For example, when an amount of active species (a concentration of active species) introduced into the center portion of the wafer 200 in the processing space 201 is greater than an amount of active species (concentration of active species) introduced into the peripheral portion of the wafer 200 by adjusting (tuning) the characteristics, a processed amount at the center portion of the wafer 200 may be greater than a processed amount at the peripheral portion of the wafer 200. On the other hand, for example, when the amount of active species (the concentration of active species) introduced into the center portion of the wafer 200 in the processing space 201 is smaller than the amount of active species (the concentration of active species) introduced into the peripheral portion of the wafer 200, the processed amount at the center portion of the wafer 200 may be smaller than the processed amount at the peripheral portion of the wafer 200.

When the electromagnetic wave shielding plate 250k is installed in the processing space 201, the height of the electromagnetic wave shielding plate 250k may be adjusted. The magnetic field strengths or the magnetic flux densities may also be adjusted (tuned) by adjusting the height of the electromagnetic wave shielding plate 250k.

Adjustment B: Bias Adjusting

After the preparation before performing the film-forming process is completed, electric potential of each of the first bias electrode 219a and the second bias electrode 219b is adjusted (tuned) based on the received process condition data. Specifically, the first impedance adjuster 220a and the second impedance adjuster 220b adjust the electric potential of the first bias electrode 219a and the electric potential of the second bias electrode 219b, respectively, so that the electric potential of the first bias electrode 219a is lower than the electric potential of the second bias electrode 219b. When the amount of active species (the concentration of active species) introduced into the center portion of the wafer 200 in the processing space 201 is greater than the amount of active species (the concentration of active species) introduced into the peripheral portion of the wafer 200 by adjusting the electric potential of the first bias electrode 219a to be lower than the electric potential of the second bias electrode 219b, the processed amount at the center portion of the wafer 200 may be greater than the processed amount at the peripheral portion of the wafer 200. On the other hand, the first impedance adjuster 220a and the second impedance adjuster 220b may adjust the electric potential of the first bias electrode 219a and the electric potential of the second bias electrode 219b, respectively, so that the electric potential of the first bias electrode 219a is higher than the electric potential of the second bias electrode 219b.

Adjustment C: Activation Adjusting

After the preparation before performing the film-forming process is completed, high-frequency power supplied to each of the first coil 250a and the second coil 250b is adjusted (tuned) based on the received process condition data. Specifically, the first high-frequency power source 250c and the second high-frequency power source 250f adjust (change), for example, the high-frequency power supplied to the first coil 250a and the high-frequency power supplied to the second coil 250b, respectively, so that the high-frequency power supplied to the first coil 250a is greater than the high-frequency power supplied to the second coil 250b. When the amount of active species (the concentration of active species) introduced into the center portion of the wafer 200 in the processing space 201 is greater than the amount of active species (the concentration of active species) introduced into the peripheral portion of the wafer 200 by adjusting the high-frequency power supplied to the first coil 250a to be greater than the high-frequency power supplied to the second coil 250b, the processed amount at the center portion of the wafer 200 may be greater than the processed amount at the peripheral portion of the wafer 200. On the other hand, the first high-frequency power source 250c and the second high-frequency power source 250f may adjust (tune), for example, high-frequency power supplied to the first coil 250a and the high-frequency power supplied to the and the second coil 250b, respectively, so that the high-frequency power supplied to the first coil 250a is smaller than the high-frequency power supplied to the second coil 250b.

[Process Gas Supplying Step S4003]

After at least one of the adjustments A to C is performed, a silicon-containing gas serving as the first process gas is supplied into the processing space 201 through the first process gas supply unit 243. The exhaust system controls the inner pressure of the processing space 201 so it reaches a predetermined pressure (a first pressure) by continuously exhausting the gas from the processing space 201. Specifically, the silicon-containing gas is supplied to the first gas supply pipe 243a by opening the valve 243d of the first gas supply pipe 243a. A flow rate of the silicon-containing gas is adjusted by the WC 243c. The silicon-containing gas with the flow rate thereof adjusted is supplied into the processing space 201 through the gas inlet 241a and is then exhausted through the exhaust pipe 222.

When the silicon-containing gas is supplied, an inert gas may be supplied into the first inert gas supply pipe 246a by opening the valve 246d of the first inert gas supply pipe 246a. A flow rate of the inert gas is adjusted by the WC 246c. The inert gas with the flow rate thereof adjusted is mixed with the silicon-containing gas in the first process gas supply pipe 243a, is supplied into the process chamber 201 through the gas inlet 241a, and is then exhausted through the exhaust pipe 222.

By performing the process gas supplying step S4003, the silicon-containing gas is adhered onto the surface of the poly-Si layer 2005 formed on the wafer 200, and thus a silicon-containing layer is formed.

[Activation Step S4004]

After the process gas supplying step S4003 is performed, a nitrogen-containing gas serving as the second process gas is supplied into the processing space 201 through the second gas supply unit 244. The inner pressure of the processing space 201 reaches a predetermined pressure (a second pressure) by continuously exhausting the gas from the processing space 201 through the exhaust system. Specifically, the nitrogen-containing gas is supplied into the second gas supply pipe 244a by opening the valve 244d of the second gas supply pipe 244a. A flow rate of the nitrogen-containing gas is adjusted by the MFC 244c. The nitrogen-containing gas with the flow rate thereof adjusted is supplied into the processing space 201 through the gas inlet 241a and is then exhausted through the exhaust pipe 222.

High-frequency power is supplied from the first high-frequency power source 250c to the first coil 250a through the first matching box 250d. The nitrogen-containing gas present in the processing space 201 is activated by an action of an electric field generated by the first coil 250a. Specifically, the nitrogen-containing gas is activated in at least one of the first plasma generation region 251, the third plasma generation region 253 and the fourth plasma generation region 254 of the processing space 201 (see FIG. 13), and thus nitrogen-containing plasma is generated.

When the nitrogen-containing gas is activated, the activated nitrogen-containing gas is supplied onto the wafer 200 placed on the substrate support 210 in the processing space 201. When the nitrogen-containing gas in an activated plasma state is supplied, the silicon-containing layer adsorbed on the surface of the poly-Si layer 2005 formed on the wafer 200 reacts with the nitrogen-containing gas in plasma state, and thus the SiN layer 2006 is generated on the surface of the poly-Si layer 2005.

When the activated nitrogen-containing gas is supplied onto the wafer 200, active species having different concentrations may be supplied to the center portion of the wafer 200 and the peripheral portion of the wafer 200 based on the received process condition data.

For example, when the adjustment A is performed, since a magnetic field strength formed by the second electromagnet 250h is greater than a magnetic field strength formed by the first electromagnet 250g, a plasma density at the peripheral portion of the fourth plasma generation region 254 is greater than a plasma density at the center portion thereof. A density of the activated plasma above the center portion of the wafer 200 is greater than a density of the activated plasma above the peripheral portion of the wafer 200. On the other hand, the magnetic field strength formed by the second electromagnet 250h may be adjusted to be smaller than the magnetic field strength formed by the first electromagnet 250g.

For example, when the adjustment B is performed, since an electric potential of the second bias electrode 219b is lower than an electric potential of the first bias electrode 219a, an amount of active species introduced into the peripheral portion of the wafer 200 is greater than an amount of active species introduced into the center portion of the wafer 200. That is, a concentration of the active species of the plasma above the center portion of the wafer 200 is greater than a concentration of the active species the plasma above the peripheral portion of the wafer 200. On the other hand, the electric potential of the second bias electrode 219b may be adjusted to be higher than the electric potential of the first bias electrode 219a.

For example, when the adjustment C is performed, since the high-frequency power supplied to the second coil 250b is greater than the high-frequency power supplied to the first coil 250a, an amount of active species supplied to the peripheral portion of the wafer 200 is greater than an amount of active species supplied to the center portion of the wafer 200. The concentration of the active species of the plasma above the center portion of the wafer 200 is greater than the concentration of the active species of the plasma above the peripheral portion of the wafer 200. On the other hand, the high-frequency power supplied to the second coil 250b may be adjusted to be smaller than the high-frequency power supplied to the first coil 250a. When the high-frequency power is supplied from the second high-frequency power source 250f to the second coil 250b through the second matching box 250e, activated plasma may also be generated in the second plasma generation region 252.

As described above, when necessary, a processed amount of the wafer 200 may be adjusted (tuned) by supplying active species having different concentrations to the center portion of the wafer 200 and the peripheral portion of the wafer 200. Specifically, when the received process condition data represents the distribution A, a thickness of the SiN layer 2006b formed at the peripheral portion of the wafer 200 may be increased by adjusting the concentration of the active species supplied to the peripheral portion of the wafer 200 to be greater than the concentration of the active species supplied to the center portion of the wafer 200. A thickness of the SiN layer 2006a formed at the center portion of the wafer 200 may be reduced by adjusting the concentration of the active species supplied to the center portion of the wafer 200 to be smaller than the concentration of the active species supplied to the peripheral portion of the wafer 200. Thus, the height distribution of the film surface of the SiN layer 2006 becomes the height distribution A′ of the target film surface (see FIG. 8). On the other hand, when the received process condition data represents the distribution B, the thickness of the SiN layer 2006a formed at the center portion of the wafer 200 may be increased by adjusting the concentration of the active species supplied to the center portion of the wafer 200 to be greater than the concentration of the active species supplied to the peripheral portion of the wafer 200. The thickness of the SiN layer 2006b formed at the peripheral portion of the wafer 200 may be reduced by adjusting the concentration of the active species supplied to the peripheral portion of the wafer 200 to be smaller than the concentration of the active species supplied to the center portion of the wafer 200. Thus, the height distribution of the film surface of the SiN layer 2006 becomes the height distribution B′ of the target film surface (e.g., see FIG. 10).

More specifically, in the activation step S4004, the height of the film surface when forming the SiN layer 2006 is adjusted based on the received process condition data so that the height of the surface of the laminated film of the poly-Si layer 2005 and the SiN layer 2006 is within a predetermined range on an overall surface of the wafer 200. Therefore, the height H1a of the surface of the SiN layer 2006b formed at the peripheral portion of the wafer 200 and the height H1b the surface of the SiN layer 2006a formed at the center portion of the wafer 200, which are obtained after performing the activation step S4004, become substantially the same as the height of the surface of the wafer 200 (e.g., see FIGS. 7A, 7B, 9A and 9B).

As necessary, when the active species having different concentrations are supplied to the center portion of the wafer 200 and the peripheral portion of the wafer 200, the SiN layer 2006 may be formed to have a density at the center portion of the wafer 200 different from a density at the peripheral portion of the wafer 200. Specifically, for example, a density of the SiN layer 2006b formed at the peripheral portion of the wafer 200 may be greater than a density of the SiN layer 2006a formed at the center portion of the wafer 200 by adjusting the concentration of the active species supplied to the peripheral portion of the wafer 200 to be greater than the concentration of the active species supplied to the center portion of the wafer 200. The density of the SiN layer 2006a formed at the center portion of the wafer 200 may be smaller than the density of the SiN layer 2006b formed at the peripheral portion of the wafer 200 by adjusting the concentration of the active species supplied to the center portion of the wafer 200 to be smaller than the concentration of the active species supplied to the peripheral portion of the wafer 200. On the other hand, the density of the SiN layer 2006b formed at the peripheral portion of the wafer 200 may be reduced, and the density of the SiN layer 2006a formed at the center portion of the wafer 200 may be increased. A composition of the SiN layer 2006 at the center portion of the wafer 200 may be formed different from a composition of the SiN layer 2006 at the peripheral portion of the wafer 200. A film characteristic, such as crystallinity, that can affect an etching rate may be formed to be different as well as the composition of the SiN layer 2006 at the center portion of the wafer 200 being different from the composition of the SiN layer 2006 at the peripheral portion of the wafer 200. Hereinafter, a characteristic including the density and the composition, that can affect the etching rate, is collectively referred to as a “film characteristic.”

[Purging Step S4005]

When a predetermined time has elapsed after the nitrogen-containing plasma is generated through the activation step S4004, the plasma disappears from the processing space 201 by turning off the high-frequency power supplied to the first coil 250a and the second coil 250b. The supply of the silicon-containing gas, which started to be supplied in the process gas supplying step S4003 and the nitrogen-containing gas, which started to be supplied in the activation step S4004, may be immediately stopped or may be continuously supplied until a predetermined time has elapsed. After the supply of the silicon-containing gas and the nitrogen-containing gas is stopped, the gas remaining in the processing space 201 is exhausted through the exhaust port 221. An inert gas may be supplied into the processing space 201 through the purge gas supply unit 245 and the gas remaining in the processing space 201 may be extruded by the inert gas. When the inert gas is supplied into the processing space 201 through the purge gas supply unit 245, a duration required to perform the purging step S4005 may be reduced, and thus throughput may be improved.

[Substrate Unloading Step S3006]

After the purging step S4005 is performed, the wafer 200 is unloaded from the processing space 201. Specifically, in the substrate unloading step S3006, the processing space 201 is purged with the inert gas, and the inner pressure of the processing space 201 after purging is adjusted to transfer the inert gas. After the inner pressure of the processing space 201 is adjusted, the substrate support 210 is lowered by the lifting mechanism 218, the lift pins 207 protrude from the through-holes 214, and the wafer 200 is placed on the lift pins 207. After the wafer 200 is placed on the lift pins 207, the gate valve 205 is opened and the wafer 200 is unloaded from the processing space 201. The wafer 200 is transferred to the apparatuses such as the height measuring apparatus 607 or the group of the patterning apparatuses 608 through 614, which perform a subsequent step. The substrate processing apparatus 606 including the processing space 201 may subsequently perform the processing on a new wafer 200.

(5) Exemplary Processing after Forming Second Silicon-Containing Layer

Next, Exemplary processing in which the wafer 200, on which the SiN layer 2006 is formed, is processed after the SiN layer 2006 is formed by the substrate processing apparatus 606 performing the second silicon-containing layer forming step S105, will be described. In this description, in the exemplary processing performed after forming the SiN layer 2006, the patterning step S109 will be described as an example, and specifically, it will be described in detail through specific examples and comparative examples thereof.

(First Specific Example According to First Embodiment)

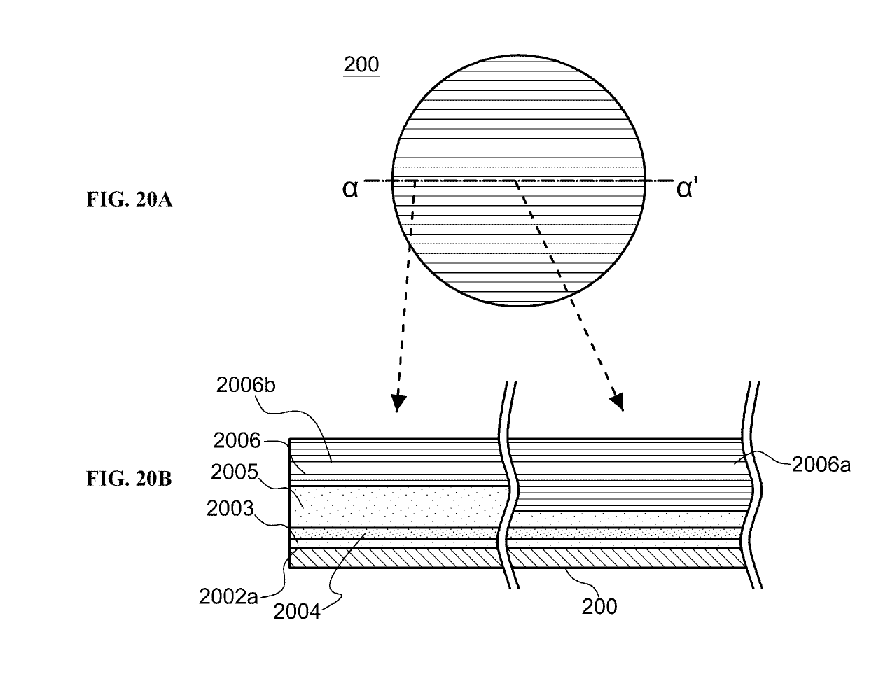

As illustrated in FIGS. 20A and 20B, as a first specific example of the patterning step S109, a case in which patterning is performed on a laminated film of the poly-Si layer 2005 which is obtained by forming the SiN layer 2006 on the poly-Si layer 2005 having the height distribution B and the SiN layer 2006 so that a height distribution of a target film surface becomes the height distribution B′ will be described.

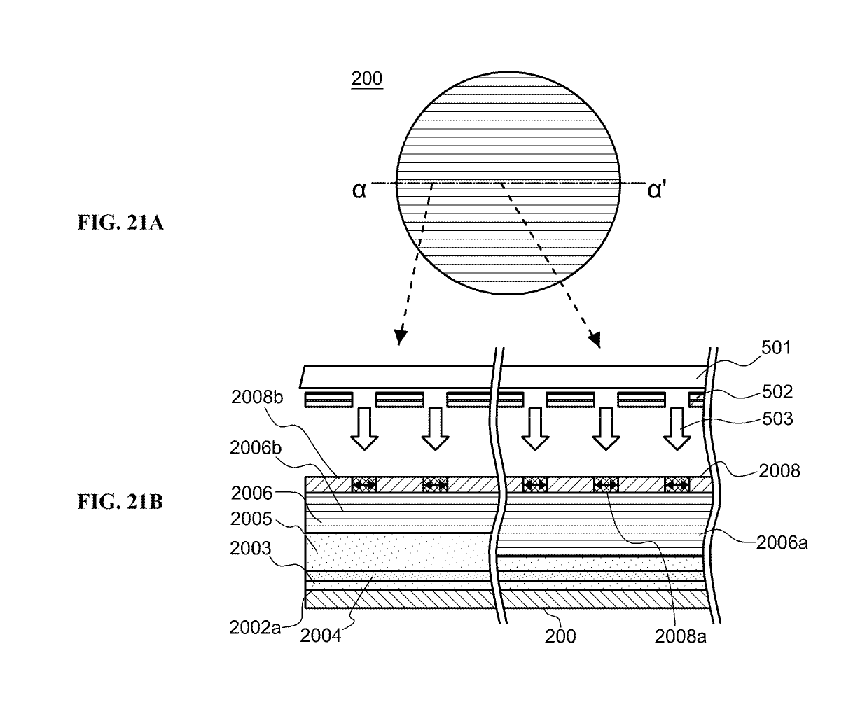

In the patterning step S109, the laminated film is patterned by sequentially performing a coating process, an exposure process, a developing process and an etching process. As illustrated in FIGS. 21A and 21B, in the coating process, the SiN layer 2006 is coated with a resist film 2008. Next, the exposure process is performed by a lamp 501 emitting light. In the exposure process, a portion (an exposed portion) of the resist film 2008 is altered by emitting exposure light 503 to the resist film 2008 through a mask 502. The resist film 2008 includes exposed portions 2008a which are altered by the exposure process and non-exposed portions 2008b which are not altered.

As described above, the SiN layer 2006, with which the resist film 2008 is coated, is formed to have a height of a surface thereof within a predetermined range on the overall surface of the wafer 200. Therefore, a distance between the concave structure surface 2002a of the wafer 200 and a surface of the resist film 2008 coated on the SiN layer 2006 is substantially constant on the overall surface of the wafer 200. Thus, in the exposure process, a distance at which the exposure light 503 reaches the surface of the resist film 2008 is substantially constant on the overall surface of the wafer 200. Therefore, a depth of focus when exposing the resist film 2008 may be uniform on the overall surface of the wafer 200. In the exposure process, since the depth of focus when exposing the resist film 2008 may be uniform on the overall surface of the wafer 200, a variation may be suppressed from occurring in a width of a pattern of the exposed portions 2008a.

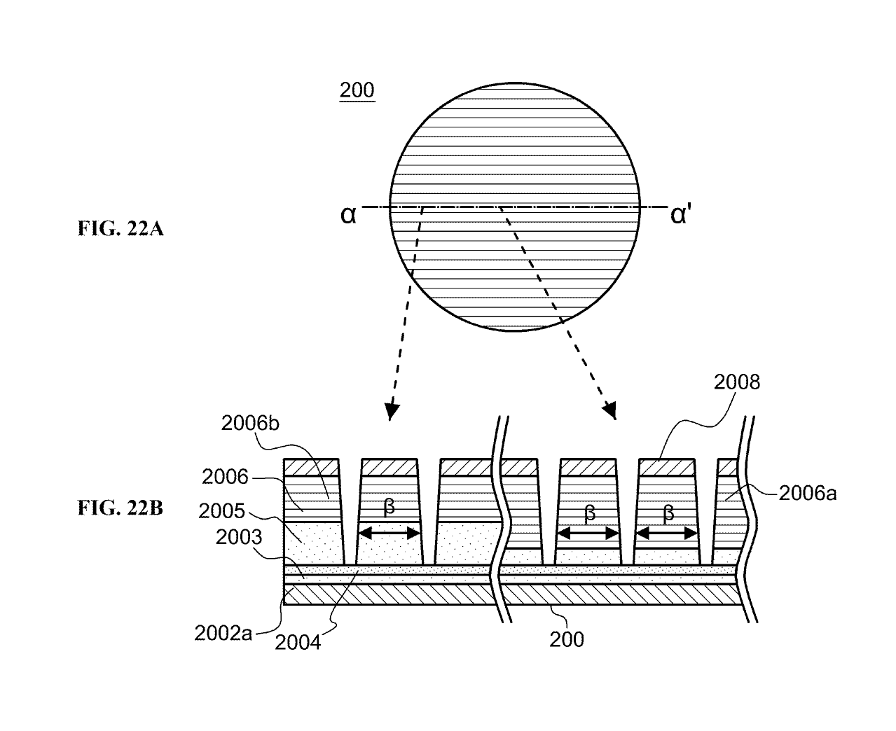

After the exposure process is performed, as illustrated in FIGS. 22A and 22B, any one of the exposed portions 2008a or the non-exposed portions 2008b [in the example of FIG. 22B, the exposed portions 2008a] is removed by performing the developing process. After the developing process is performed, the etching process is performed. In the etching process, the laminated film of the poly-Si layer 2005 and the SiN layer 2006 is etched using the resist film 2008, on which the developing process is performed, as a mask.

The variation of the width of the pattern of the exposed portions 2008a of the resist film 2008 is suppressed as described above. Therefore, the etching process may be performed on the overall surface of the wafer 200 with a constant etching condition. That is, an etching gas may be uniformly supplied to each of the center portion of the wafer 200 and the peripheral portion of the wafer 200, and a width β of the poly-Si layer 2005 (hereinafter referred to as a “pillar”) after the etching is substantially constant on the overall surface of the wafer 200.

When the width β of the pillar formed through the etching process is substantially the same on the overall surface of the wafer 200, a characteristic of a gate electrode of a FinFET that can be obtained through the etching process is constant on the overall surface of the wafer 200. As a result, a yield of the FinFET may be improved.

(Second Specific Example According to First Embodiment)

Next, as a second specific example of the patterning step S109, a case in which patterning is performed on a laminated film of the poly-Si layer 2005 and the SiN layer 2006 of which a density at the center portion of the wafer 200 differs from a density at the peripheral portion of the wafer 200 will be described.

In the second specific example, the density of the SiN layer 2006 at the center portion of the wafer 200 differs from the density of the SiN layer 2006 at the peripheral portion of the wafer 200. Specifically, when the SiN layer 2006 is formed, a degree of activity of ammonia (NH₃) gas serving as the second process gas (a nitrogen-containing gas) at the center portion of the wafer 200 differs from a degree of activity of ammonia (NH₃) gas at the peripheral portion of the wafer 200, and thus, for example, the density of the SiN layer 2006 at the center portion of the wafer 200 differs from the density of the SiN layer 2006 at the peripheral portion of the wafer 200.

In the second specific example, a coating process, an exposure process and a developing process in the patterning step S109 are the same as those in the above-described first specific example. After the developing process is performed, an etching process in which the laminated film of the poly-Si layer 2005 and the SiN layer 2006 is etched is performed.

When the etching process is performed, an etching completion time of the etched SiN layer 2006 at the center portion of the wafer 200 may differ from an etching completion time of the etched SiN layer 2006 at the peripheral portion thereof. Specifically, for example, when a thickness of the SiN layer 2006 at the center portion of the wafer 200 is small and a thickness of the SiN layer 2006 at the peripheral portion of the wafer 200 is large, the etching at the center portion of the wafer 200 may be completed before the etching at the peripheral portion of the wafer 200. When the etching at the peripheral portion of the wafer 200 is completed, the SiN layer 2006 may be over-etched at the center portion of the wafer 200.

In the second specific example, as described above, since the density of the SiN layer 2006 at the center portion of the wafer 200 differs from the density of the SiN layer 2006 at the peripheral portion of the wafer 200, an etching rate of the SiN layer 2006 at the center portion of the wafer 200 may differ from an etching rate of the SiN layer 2006 at the peripheral portion of the wafer 200. Therefore, the etching of the SiN layer 2006 may be uniformly performed on the overall surface of the wafer 200. When the etching of the SiN layer 2006 is uniformly performed, for example, a problem in that the etching of another portion is not completed when the etching of a portion is completed or another portion is over-etched when the etching of the portion is completed may be addressed.

Therefore, a characteristic of a gate electrode of a FinFET that can be obtained by performing the etching process may be constant on the overall surface of the wafer 200, and as a result, a yield of the FinFET may be improved.

### First Comparative Example

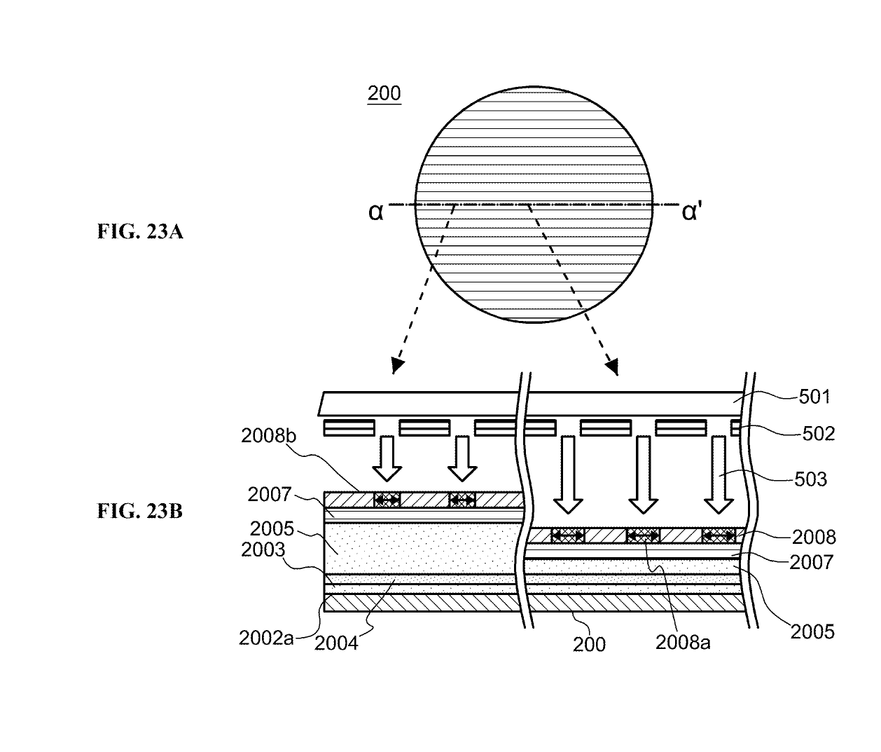

Next, a first comparative example compared with the above-described first and second specific examples will be described. As illustrated in FIGS. 23A and 23B, in the first comparative example, an SiN layer 2007 formed on the poly-Si layer 2005 differs from that in each of the above-described specific examples, and an adjustment (a tuning) is not performed on the SiN layer 2007 to have a height of a surface of the SiN layer 2007 within a predetermined range on the overall surface of the wafer 200.

Since the adjustment (the tuning) as described in the first embodiment is not performed in the first comparative example, a thickness of the SiN layer 2007 at the center portion of the wafer 200 is substantially the same as a thickness of the SiN layer 2007 at the peripheral portion of the wafer 200. Therefore, a height of a surface of a laminated film of the poly-Si layer 2005 and the SiN layer 2007 at the center portion of the wafer 200 differs from the height of the surface of the laminated film at the peripheral portion of the wafer 200.

In an exposure process, since a distance at which the exposure light 503 reaches the surface of the resist film 2008 at the center portion of the wafer 200 differs from the distance at the peripheral portion of the wafer 200, a depth of focus when exposing the resist film 2008 is not uniform on the overall surface of the wafer 200. Therefore, a variation occurs in a width of a pattern of the exposed portions 2008a.

When the variation occurs in the width of the pattern of the exposed portions 2008a, the width β of a pillar formed through an etching process, which will be performed later, is not constant on the overall surface of the wafer 200, and the width β of the pillar at the center portion of the wafer 200 differs from the width β of the pillar at the peripheral portion of the wafer 200. Therefore, a variation occurs in a characteristic of a gate electrode of a FinFET that can be obtained by performing the etching process.

On the other hand, in the above-described first specific example according to the first embodiment, since a height distribution is adjusted (tuned) by the SiN layer 2006 in the second silicon-containing layer forming step S105, the width β of the pillar is constant on the overall surface of the wafer 200. Therefore, compared to the first comparative example, a FinFET without a variation in its characteristic may be formed, and a yield of the FinFET may be significantly improved.

### Second Comparative Example

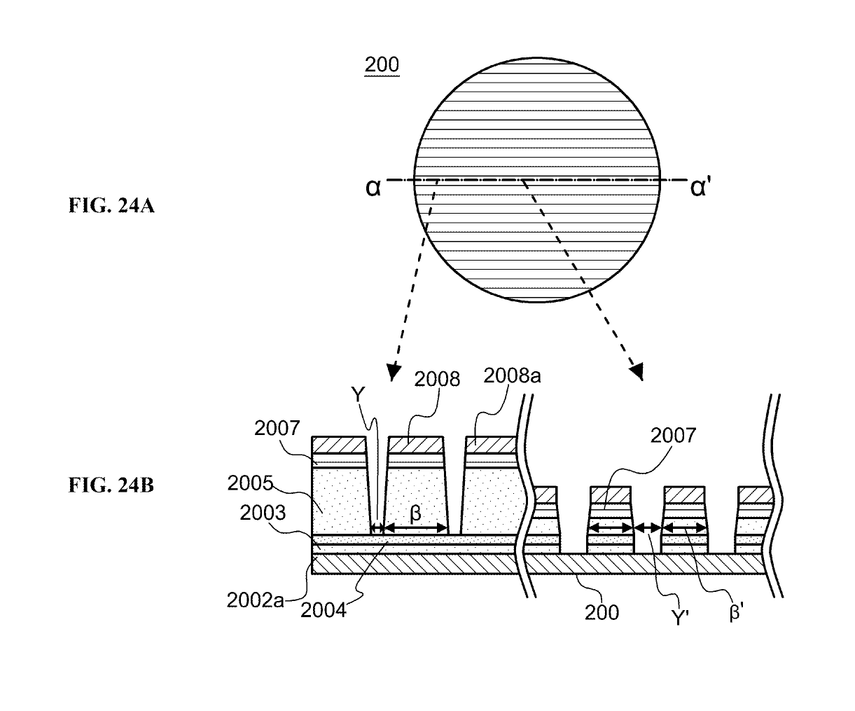

Next, a second comparative example compared with the above-described first and second specific examples will be described. As illustrated in FIGS. 24A and 24B, in the second comparative example, while an adjustment (a tuning) of the SiN layer 2007 is not performed like in the first comparative example, a variation does not occur in a width of a pattern of the exposed portions 2008a of the resist film 2008 like in the above-described specific examples. That is, in the second comparative example, while the exposed portions 2008a are removed through a developing process, a variation of a width of a gap between the non-exposed portions 2008b after the removal is suppressed.

In the second comparative example, an etching process is performed after the exposed portions 2008a are removed through the developing process. The laminated film of the poly-Si layer 2005 and the SiN layer 2007 is etched using the non-exposed portions 2008b remaining after the developing process is performed as a mask. A height of a surface of the laminated film at the center portion of the wafer 200 differs from a height of the surface of the laminated film at the peripheral portion of the wafer 200. For example, in the etching process, when an etching time is set according to an etching amount based on the height at the center portion of the wafer 200, while the laminated film at the center portion of the wafer 200 is etched by a desired amount, an etching object remains at the peripheral portion of the wafer 200. In order to improve this problem, for example, when the etching time is set according to an etching amount based on the height at the peripheral portion of the wafer 200, while the laminated film at the peripheral portion of the wafer 200 is etched by a desired amount, the laminated film at the center portion of the wafer 200 is over-etched and a sidewall of a pillar, the gate insulating film 2004 and the device isolation film 2003 are also etched.

By etching the sidewall of the pillar due to the over-etching, an interval between poly-Si films 2005 constituting pillars is increased. Therefore, a distance γ between pillars at the peripheral portion of the wafer 200 differs from a distance γ ′ between pillars at the center portion of the wafer 200. That is, since a width of the poly-Si film 2005 constituting the pillar is not constant on the overall surface of the wafer 200, the width β of the pillar at the peripheral portion of the wafer 200 differs from a width β ′ of the pillar at the center portion thereof.

A characteristic of a gate electrode of a FinFET is easily affected by the widths β and β ′ of the pillar. Therefore, when a variation occurs in the widths β and β ′ of the pillar, a variation occurs in the characteristic of the gate electrode of the FinFET formed using the pillar. That is, when the variation occurs in the widths β and β ′ of the pillar, there is a problem in that a yield of the FinFET is decreased.

On the other hand, in the above-described first specific example according to the present embodiment, since a height distribution is adjusted (tuned) by the SiN layer 2006 in the second silicon-containing layer forming step S105, the width β of the pillar may be constant on the overall surface of the wafer 200, and a FinFET without a variation in its characteristic may be formed compared to the second comparative example. The yield of the FinFET may be significantly improved.

### Third Comparative Example

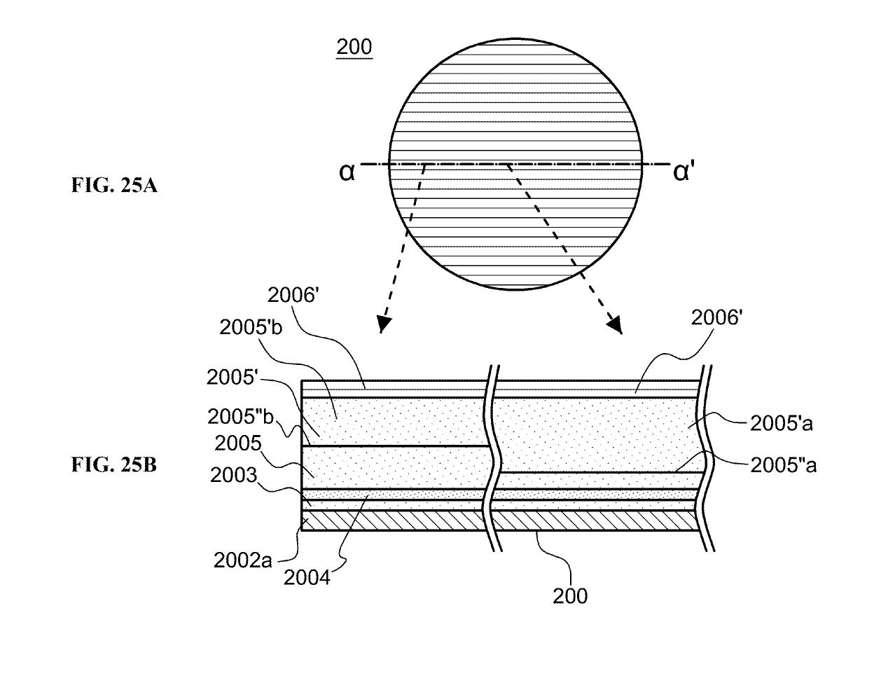

Next, a third comparative example compared with the above-described first and second specific examples will be described. In the third comparative example, a variation of a height of a surface of the poly-Si layer 2005 is adjusted (tuned) by a method different from the above-described first specific example according to the first embodiment. Specifically, as illustrated in FIGS. 25A and 25B, for example, a second poly-Si layer 2005′ formed of polycrystalline silicon (polysilicon) is formed to be constant on the poly-Si layer 2005 having the height distribution B, and a variation of a height of a film surface is adjusted (tuned) by the second poly-Si layer 2005′.

In the third comparative example, the second poly-Si layer 2005′ is formed through the following processes. The wafer 200 on which the poly-Si layer 2005 is formed is loaded into the first silicon-containing layer forming apparatus 603 used in the first silicon-containing layer forming step S102 after the polishing step S103 and the height measuring step S104 are performed. The first silicon-containing layer forming apparatus 603 into which the wafer 200 is loaded forms the second poly-Si layer 2005′ formed of polycrystalline silicon like the poly-Si layer 2005 on the poly-Si layer 2005 of the wafer 200.

When the second poly-Si layer 2005′ is formed, a height of a surface of the second poly-Si layer 2005′ is adjusted (tuned) to be substantially constant on the surface of the wafer 200 after a process condition for correcting the variation of the height of the surface of the poly-Si layer 2005 is determined based on height distribution data of the film surface obtained in the height measuring step S104. When the second poly-Si layer 2005′ is formed, an adjustment (the tuning) may be performed using an activation control in the process chamber as described in the first embodiment.

After the second poly-Si layer 2005′ is formed, the wafer 200 is unloaded from the first silicon-containing layer forming apparatus 603, and the unloaded wafer 200 is loaded into the substrate processing apparatus 606. The substrate processing apparatus 606 into which the wafer 200 is loaded forms a SiN layer 2006′ which functions as a hard mask on the second poly-Si layer 2005′ of the wafer 200. With this method, a height of a surface of the SiN layer 2006′ may also be substantially constant on the overall surface of the wafer 200 in the third comparative example.

However, according to the results of intensive research by the inventors of the present application, they found that a method according to the third comparative example has problems to be described below. In the third comparative example, each of the poly-Si layer 2005 and the second poly-Si layer 2005′ is formed through separate steps. The polishing step S103 is performed between the steps. That is, the poly-Si layer 2005 and the second poly-Si layer 2005′ are formed of the same chemical compound, but are not formed continuously, and damage due to polishing may occur on the poly-Si layer 2005 and the second poly-Si layer 2005′. Therefore, a composition of the film is altered in the vicinity of an interface between the poly-Si layer 2005 and the second poly-Si layer 2005′. Therefore, interface layers 2005″a and 2005″b having a composition different from that of each of the poly-Si layer 2005 and the second poly-Si layer 2005′ may be formed.

When the interface layers 2005″a and 2005″b are formed, an etching rate of the poly-Si layer 2005 and the second poly-Si layer 2005′ differs from an etching rate of the interface layers 2005″a and 2005″b. That is, since the poly-Si layer 2005 and the second poly-Si layer 2005′ are originally formed to have the same chemical compound, the respective etching rates thereof have to be the same, but when the interface layers 2005″a and 2005″b are present between the poly-Si layer 2005 and the second poly-Si layer 2005′, the etching rate of the poly-Si layer 2005 and the second poly-Si layer 2005′ is not the same as the etching rate of the interface layers 2005″a and 2005″b. In a patterning step, it is difficult to calculate the etching rate in consideration of the overall poly-Si layer. Therefore, in the patterning step, problems such as over etching and under etching may occur.

When the interface layers 2005″a and 2005″b are present between the poly-Si layer 2005 and the second poly-Si layer 2005′, there is a problem in that a degree of bonding between the poly-Si layer 2005 and the second poly-Si layer 2005′ is reduced.

On the other hand, in the above-described first specific example according to the first embodiment, the variation of the height of the surface of the poly-Si layer 2005 is not adjusted by forming the second poly-Si layer 2005′ link in the third comparative example, and since the variation is adjusted (tuned) using the SiN layer 2006 which functions as a hard mask, the following risks may be reduced. In the first specific example according to the present embodiment, since the interface layers 2005″a and 2005″b like in the third comparative example are not formed on a layer of the poly-Si layer 2005, the etching rate with respect to the poly-Si layer 2005 may be easily calculated. Therefore, the problems such as over etching and under etching in the patterning step may be suppressed. Further, in the first specific example according to the first embodiment, since there is no need to form the second poly-Si layer 2005′, the number of processes is one smaller than the number of processes in the third comparative example, and as a result, a high manufacturing throughput is achieved.

In the above-described second specific example according to the first embodiment, since a composition of the SiN layer 2006 at the center portion of the wafer 200 differs from a composition of the SiN layer 2006 at the peripheral portion of the wafer 200, the SiN layer 2006 may be uniformly etched. Therefore, in the second specific example according to the first embodiment, the problems such as over etching and under etching in the patterning step like in the third comparative example may be further suppressed.

(6) Effects of First Embodiment

According to the first embodiment, one or more of the following effects may be obtained.

(a) According to the first embodiment, the variation of the height on the overall surface of the poly-Si layer 2005 is adjusted (tuned) by forming the SiN layer 2006 on the poly-Si layer 2005 according to the process condition determined based on the height distribution data of the poly-Si layer 2005 after the polishing is performed. Therefore, since the height of the surface of the laminated film of the poly-Si layer 2005 and the SiN layer 2006 is substantially constant on the overall surface of the wafer 200, the depth of focus when the resist film 2008 on the SiN layer 2006 is exposed is constant in the patterning step S109, which will be performed subsequently. Therefore, the width β of the pillar that can be obtained by the etching is constant on the overall surface of the wafer 200. That is, since the variation of the line width of the pattern of a circuit or the like may be suppressed from occurring, a FinFET without a variation in the characteristic may be formed even when a miniaturized pattern is included. As a result, a yield of the FinFET may be significantly improved.

(b) According to the first embodiment, the variation of the height of the surface of the poly-Si layer 2005 is adjusted (tuned) using the SiN layer 2006 formed by a chemical compound different from that of the poly-Si layer 2005. Therefore, for example, unlike a case in which the variation of the height is corrected using the film formed by the same chemical compound like in the third comparative example, since the etching rate of the poly-Si layer 2005 is not changed by the interface layers 2005″a and 2005″b, the etching rate with respect to the poly-Si layer 2005 may be easily calculated. Therefore, problems such as over etching and under etching in the patterning step may be suppressed. Since the variation of the height of the surface of the poly-Si layer 2005 is adjusted (tuned) using the SiN layer 2006 which functions as a hard mask, the number of processes is one smaller than the number of processes in the third comparative example, and as a result, a high manufacturing throughput is achieved. For example, when the poly-Si layer 2005 functions as an insulating layer, since the interface layers 2005″a and 2005″b are not formed as in the third comparative example, a leakage path due to the interface layers 2005″a and 2005″b may not occur, and a risk of a leakage current being generated in the insulating layer may be suppressed.

(c) According to the first embodiment, when the nitrogen-containing gas serving as the process gas for forming the SiN layer 2006 is supplied, the height of the surface of the laminated film of the poly-Si layer 2005 and the SiN layer 2006 is adjusted (tuned) by supplying active species having different concentrations at the center portion of the wafer 200 and at the peripheral portion thereof. Therefore, the height of the surface of the laminated film may be corrected by adjusting the processed amount at each of the center portion of the wafer 200 and the peripheral portion of the wafer 200 to be different from each other while the SiN layer 2006 is simultaneously formed at each of the center portion of the wafer 200 and the peripheral portion of the wafer 200. That is, since a correction of the height is performed using a degree of activity of the nitrogen-containing gas, the manufacturing throughput of the FinFET may not be reduced, and the variation may be suppressed from occurring in the characteristic of the FinFET.

(d) According to the first embodiment, a film characteristic of the SiN layer 2006 as well as the height of the SiN layer 2006 at the center portion of the wafer 200 may differ from a film characteristic of the SiN layer 2006 at the peripheral portion of the wafer 200 by supplying active species having different concentrations at the center portion of the wafer 200 and at the peripheral portion of the wafer 200. Therefore, the density of a side of the SiN layer 2006 may be small and the density of another side thereof may be large, and thus the etching rate of the SiN layer 2006 at the center portion of the wafer 200 may differ from the etching rate of the SiN layer 2006 at the peripheral portion of the wafer 200, and the SiN layer 2006 may be uniformly etched on the overall surface of the wafer 200.

(e) Further, according to the present embodiment, a single substrate processing system 600 may be embodied by linking the apparatuses 601 through 614 which perform the steps S101 to S109 for manufacturing the FinFET. Therefore, the apparatuses 601 through 614 in the substrate processing system 600 may be controlled by linking the apparatuses 601 through 614 so that the steps S101 to S109 are efficiently performed, and as a result, the manufacturing throughput of the FinFET may be improved.

(7) Other embodiments

As described above, the first embodiment described herein has been described in detail, but the described technique is not limited to the above-described first embodiment, and various other embodiments may be changed without departing from the scope and spirit of the described technique.

(Processing Sequence)

In the above-described first embodiment, a specific example of the adjustment (the tuning) performed by the substrate processing apparatus 606 is a case in which the magnetic field is adjusted like the adjustment A illustrated in FIG. 19. Specifically, when a magnetic field strength formed by the second electromagnet 250h is greater than a magnetic field strength formed by the first electromagnet 250g, a degree of activity of plasma generated above the peripheral portion of the wafer 200 is greater than a degree of activity of plasma generated above the center portion of the wafer 200. However, the adjustment (the tuning) described herein is not limited thereto, for example, the adjustment (the tuning) to be described below is also possible.

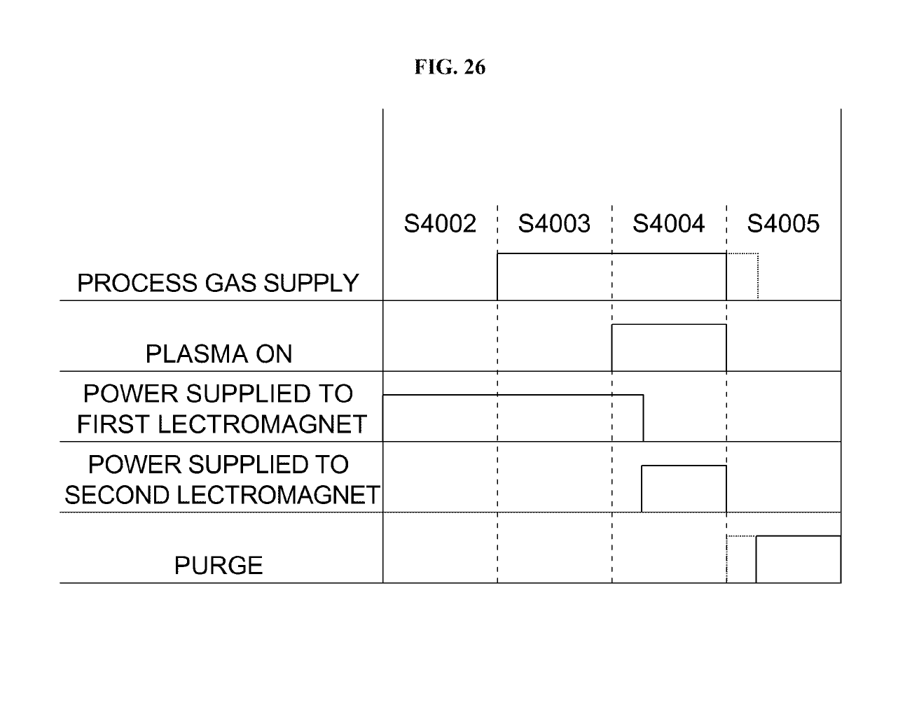

FIG. 26 illustrates a processing sequence in a second embodiment of the method of manufacturing a semiconductor device described herein. In the processing sequence illustrated in FIG. 26, a magnetic field is generated by the first electromagnet 250g and then a magnetic field is generated by the second electromagnet 250h. When processing is performed according to the processing sequence illustrated in FIG. 26, the amount of the film formed at the peripheral portion of the wafer 200 is greater than the amount of the film formed at the center portion of the wafer 200. On the other hand, when a magnetic field is generated by the second electromagnet 250h and then a magnetic field is generated by the first electromagnet 250g, the amount of the film formed at the center portion of the wafer 200 is smaller than the amount of the film formed at the peripheral portion of the wafer 200.

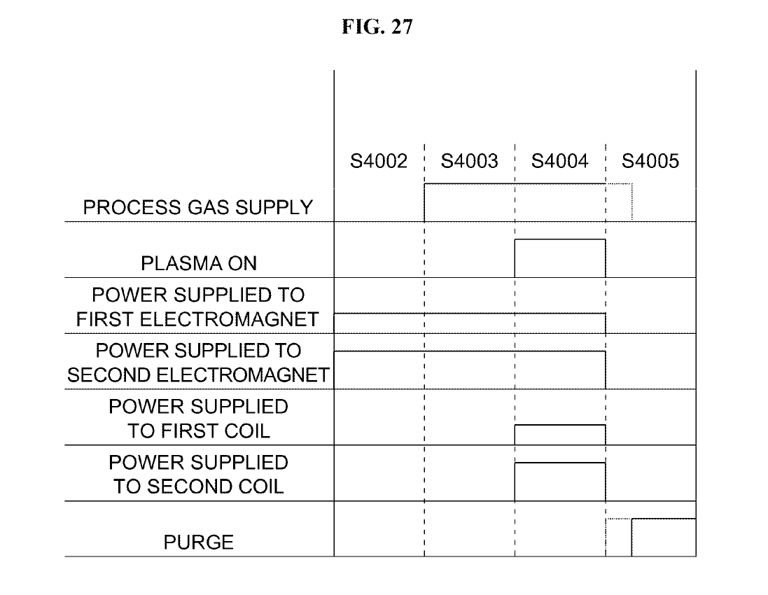

FIG. 27 illustrates a processing sequence in a third embodiment of the method of manufacturing a semiconductor device described herein. In the processing sequence illustrated in FIG. 27, a configuration in which power supplied to the second coil 250b is greater than power supplied to the first coil 250a is added to the processing sequence illustrated in FIG. 19. When processing is performed according to the processing sequence illustrated in FIG. 27, the amount of the film formed at the peripheral portion of the wafer 200 is greater than the amount of the film formed at the center portion of the wafer 200. On the other hand, when the power supplied to the first electromagnet 250g is greater than the power supplied to the second electromagnet 250h and power supplied to the first coil 250a is greater than power supplied to the second coil 250b, the amount of the film formed at the center portion of the wafer 200 is greater than the amount of the film formed at the peripheral portion of the wafer 200.

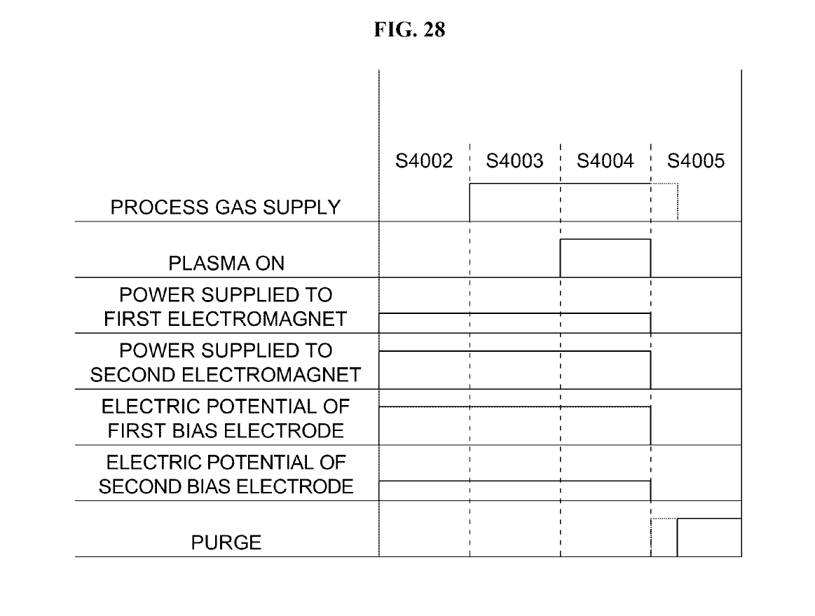

FIG. 28 illustrates a processing sequence in a fourth embodiment of the method of manufacturing a semiconductor device described herein. In the processing sequence illustrated in FIG. 28, a configuration in that an electric potential of the first bias electrode 219a is greater than an electric potential of the second bias electrode 219b is added to the processing sequence illustrated in FIG. 19. When processing is performed according to the processing sequence illustrated in FIG. 28, the amount of the film formed at the peripheral portion of the wafer 200 is greater than the amount of the film formed at the center portion of the wafer 200. On the other hand, when the power supplied to the first electromagnet 250g is greater than the power supplied to the second electromagnet 250h and the electric potential of the second bias electrode 219b is greater than the electric potential of the first bias electrode 219a, the amount of the film formed at the center portion of the wafer 200 is smaller than the amount of the film formed at the peripheral portion of the wafer 200.

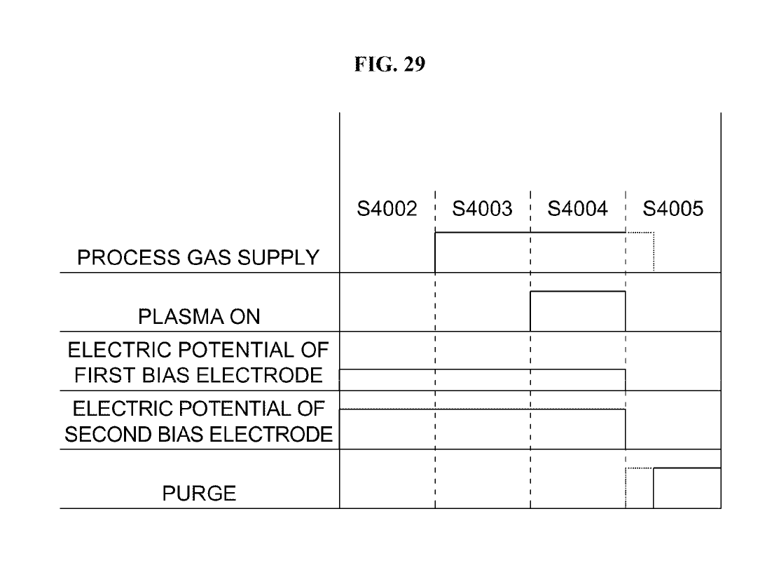

FIG. 29 illustrates a processing sequence in a fifth embodiment of the method of manufacturing a semiconductor device described herein. In the processing sequence illustrated in FIG. 29, an electric potential of the second bias electrode 219b is greater than an electric potential of the first bias electrode 219a. When processing is performed according to the processing sequence illustrated in FIG. 29, a height of a surface of a laminated film may be corrected by forming the SiN layer 2006 having the height distribution A′ on the poly-Si layer 2005 having the height distribution A (see FIG. 8).

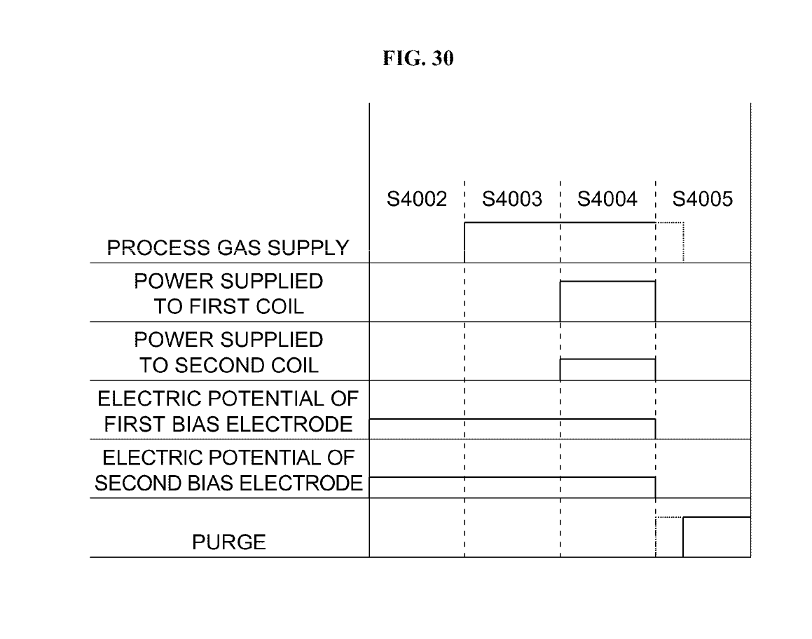

FIG. 30 illustrates a processing sequence in a sixth embodiment of the method of manufacturing a semiconductor device described herein. In the processing sequence illustrated in FIG. 30, high-frequency power supplied to the first coil 250a is greater than high-frequency power supplied to the second coil 250b. When processing is performed according to the processing sequence illustrated in FIG. 30, a height of a surface of a laminated film may be corrected by forming the SiN layer 2006 having the height distribution B′ on the poly-Si layer 2005 having the height distribution B (see FIG. 10).

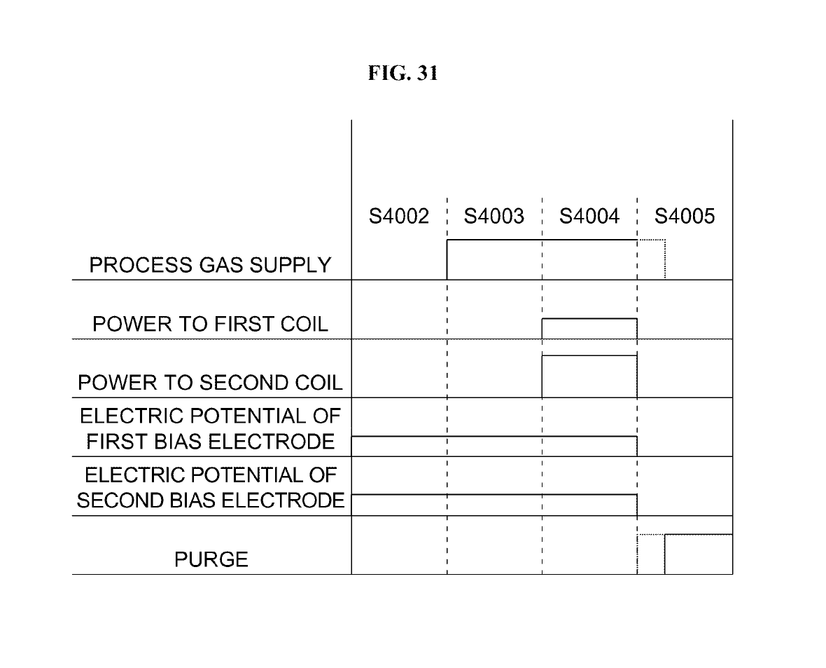

FIG. 31 illustrates a processing sequence in a seventh embodiment of the method of manufacturing a semiconductor device described herein. In the processing sequence illustrated in FIG. 31, high-frequency power supplied to the first coil 250a is smaller than high-frequency power supplied to the second coil 250b. When processing is performed according to the processing sequence illustrated in FIG. 31, for example, a height of a surface of a laminated film may be corrected by forming the SiN layer 2006 having the height distribution A′ of a target film surface on the poly-Si layer 2005 having the height distribution A (see FIG. 8).

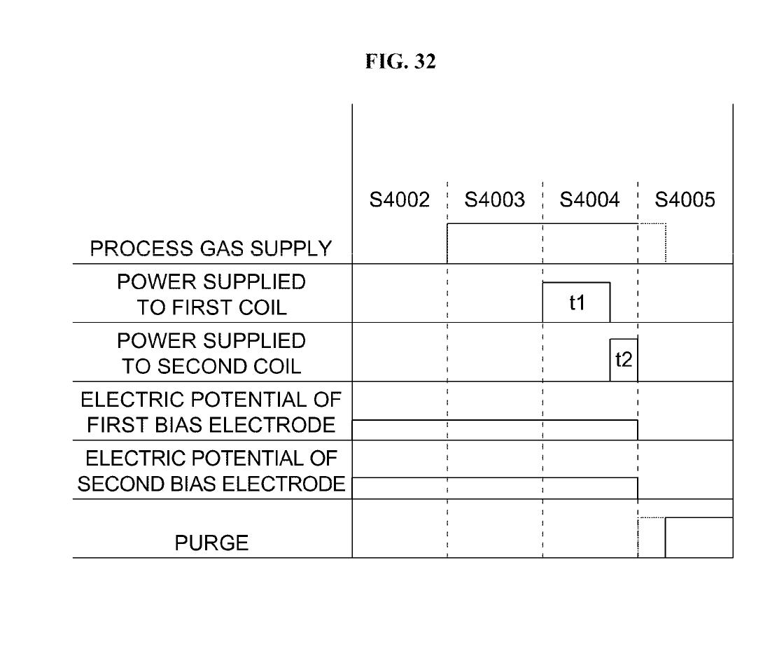

FIG. 32 illustrates a processing sequence in an eighth embodiment of the method of manufacturing a semiconductor device described herein. In the processing sequence illustrated in FIG. 32, high-frequency power is supplied to the first coil 250a for a time duration t1, and then high-frequency power is supplied to the second coil 250b for a time duration t2. In the processing sequence illustrated in FIG. 32, the time duration t1 is greater than the time duration t2. When processing is performed according to the processing sequence illustrated in FIG. 32, a height of a surface of a laminated film may be corrected by forming the SiN layer 2006 having the height distribution B′ on the poly-Si layer 2005 having the height distribution B (see FIG. 10). Further, in the processing sequence illustrated in FIG. 32, the high-frequency power is supplied to the second coil 250b after the high-frequency power is supplied to the first coil 250a, but the power may alternatively be supplied to the first coil 250a after the power is supplied to the second coil 250b.

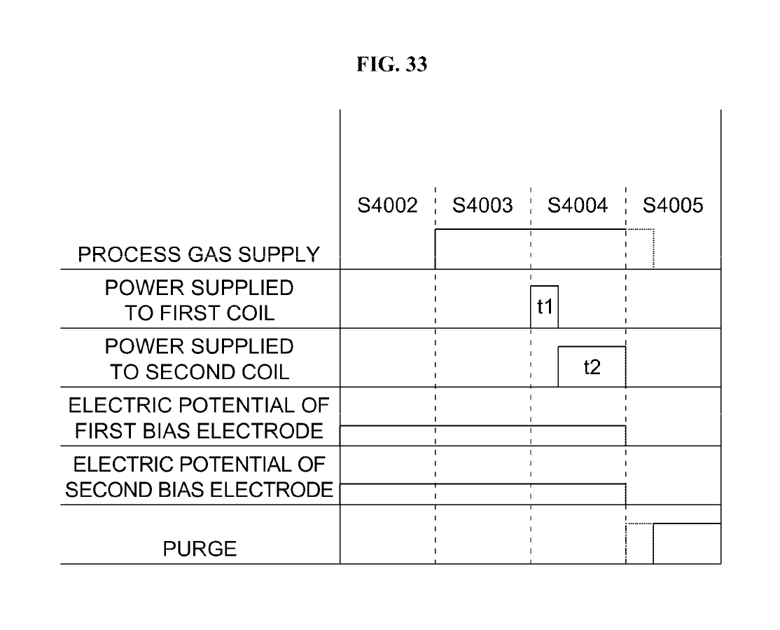

For example, FIG. 33 illustrates a processing sequence in a ninth embodiment of the method of manufacturing the semiconductor device described herein. In the processing sequence illustrated in FIG. 33, the time duration t1 is smaller than the time duration t2 unlike in the processing sequence illustrated in FIG. 32. When processing is performed according to the processing sequence illustrated in FIG. 33, for example, a height of a surface of a laminated film may be corrected by forming the SiN layer 2006 having the height distribution A′ on the poly-Si layer 2005 having the height distribution A (see FIG. 8). In the processing sequence illustrated in FIG. 33, high-frequency power is supplied to the second coil 250b after high-frequency power is supplied to the first coil 250a, but the power may alternatively be supplied to the first coil 250a after the power is supplied to the second coil 250b.

(Activation Means)

In the above-described first to ninth embodiments, the case in which plasma is generated in the processing space 201 using the first coil 250a, the first electromagnet 250g and the second electromagnet 250h is exemplified, but the described technique is not limited thereto. For example, when the first coil 250a is not installed, plasma may be generated in the processing space 201 using the second coil 250b, the first electromagnet 250g and the second electromagnet 250h. When only the second coil 250b is used, plasma is mainly generated in the second plasma generation region 252, but the distribution of the plasma may be adjusted by diffusing active species generated in the second plasma generation region 252 at the center portion of the wafer 200 using at least one of the first electromagnet 250g and the second electromagnet 250h.

In the above-described first to ninth embodiments, the case in which the regions having the different concentrations of the active species are divided into the center portion of the wafer 200 and the peripheral portion thereof is exemplified, but the described technique is not limited thereto. A region from the center portion of the wafer 200 to the peripheral portion thereof may be further subdivided, and the height of the silicon-containing layer may be adjusted according to the subdivided locations. Specifically, the wafer 200 may be divided into, for example, three regions such as the center portion of the wafer 200, the peripheral portion thereof and a middle region between the center portion and the peripheral portion, and an adjustment may be performed on each of the regions.

(Silicon-Containing Layer)

In the above-described first to ninth embodiments, the SiN layer 2006 is exemplified as the second silicon-containing layer, but the described technique is not limited thereto. The second silicon-containing layer is not limited thereto, and the silicon nitride film may be a silicon-containing layer formed by a chemical compound different from that of the first silicon-containing layer. Further, another element may be contained. For example, the second silicon-containing layer may include any one of an oxide film, a nitride film, a carbide film, an oxynitride film, a metal film or a combination thereof

Similarly, the first silicon-containing layer is not limited to the poly-Si layer 2005. The first silicon-containing layer may be a film that can fill uneven portions (Fin structures) formed on the wafer 200, a film obtained by the film-forming processing such as CVD or a film obtained through processing such as oxidation processing, nitridation processing, oxynitridation processing and spatter processing. The height distribution may be adjusted through the above-described processing. When the spatter processing or the film-forming processing is performed, anisotropic processing and isotropic processing may be combined. When the anisotropic processing and the isotropic processing are combined, the height distribution may be more precisely adjusted.

In the above-described first to ninth embodiments, the cases in which the film using different apparatuses is formed in the first silicon-containing layer forming step S102 and the second silicon-containing layer forming step S105 are exemplified, but the described technique is not limited thereto. For example, the first silicon-containing layer forming step S102 may be performed in the substrate processing apparatus 606.

In the above-described first to ninth embodiments, the case in which the variation of the height of the film surface is adjusted (tuned) using the SiN layer 2006 which functions as a hard mask is exemplified, for example, the variation of the height of the film surface may be adjusted (tuned) in the same manner as the steps such as the insulating film forming step and the electrode film forming step. When the embodiments described herein is applied to the insulating film forming step, problems to be described below may be addressed. For example, when the insulating film is formed as the silicon-containing layer, there is a problem in that a leakage path may be formed between the first layer 2005 and the second layer 2005′ of a layer structure described in the above-described third comparative example (see FIGS. 25A and 25B). The leakage path refers to a path such as a gap in which current leaks. Since the polishing step is performed after the first layer 2005 having the layer structure is formed, a surface of the first layer 2005 is terminated or damage due to polishing may occur when the second layer 2005′ is formed. Although the second layer 2005′ is formed, a bonding force between the first layer 2005 and the second layer 2005′ is reduced, and thus a gap in which a current leaks is formed. On the other hand, when the second layer 2005′ is not formed on the first layer 2005 unlike the described technique and a layer structure in which the layer 2006 having a chemical compound different from that of the first layer 2005 is formed is employed (see FIGS. 7A, 7B, 9A and 9B), the leakage path may be suppressed from occurring, and thus a risk of a leakage current being generated in the insulating film may be suppressed. Further, as described above, since the etching rate may be easily calculated, risks in the patterning step such as over etching or under etching may be suppressed. Since the second layer 2005′ forming step is reduced, the high throughput may be achieved.

(Substrate)

In the above-described first to ninth embodiments, the 300 mm wafer is exemplified as the substrate, but the described technique is not limited thereto. The described technique may be applied to, for example, a large-sized substrate such as the 450 mm wafer, and when the described technique is applied to such a large-sized substrate, the described technique is more effective. This is because that the large-sized substrate is more significantly affected by the CMP step S103. That is, in the large-sized substrate, there is a tendency that a height difference between a poly-Si layer 2005c and a poly-Si layer 2005d (see FIGS. 7A 7B, 9A and 9B) is further increased. However, in the second silicon-containing layer forming step S105 in the same manner as the described technique, when the variation of a height of a film surface is adjusted (tuned), a variation of a characteristic may also be suppressed from occurring on the large-sized substrate.

(System Configuration)

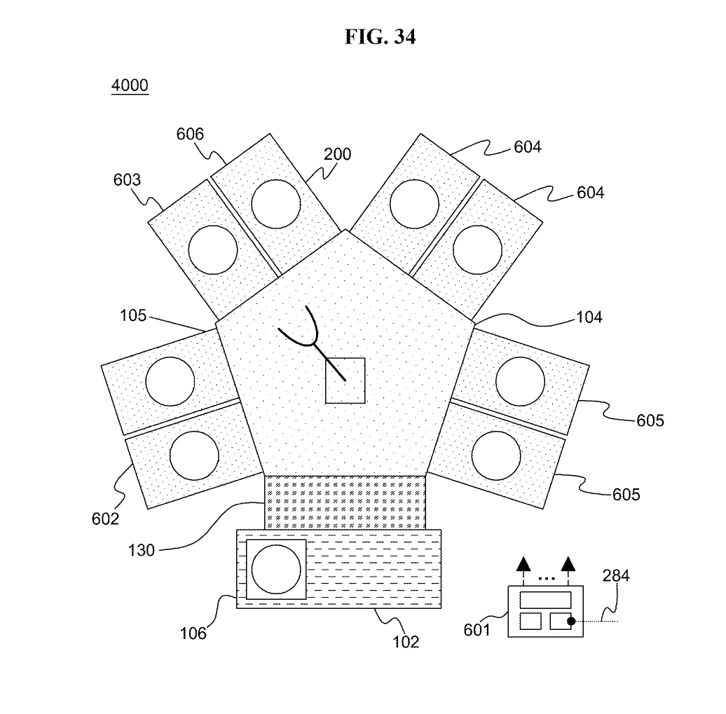

In the above-described first to ninth embodiments, the system which controls a manufacturing line of a semiconductor device (e.g., a FinFET) is exemplified as the substrate processing system 600, but the described technique is not limited thereto. The substrate processing system described herein may be, for example, a cluster-type apparatus system 4000 such as the substrate processing system according to the second embodiment described herein illustrated in FIG. 34. The substrate processing system described herein may also be an inline-type apparatus system. In the cluster-type apparatus system 4000, a transfer time of the wafer 200 between the processing apparatuses 602 through 606 may be reduced, and thus manufacturing throughput of the semiconductor device may be improved. For example, the vacuum transfer chamber 104 may be installed between the processing apparatuses 602 through 606. Using the vacuum transfer chamber 104, an impurity may be suppressed from being adsorbed into a film of an outermost surface formed on the wafer 200. The impurity refers to, for example, a material containing an element other than an element constituting the film of the outermost surface.

(Semiconductor Device)

In the above-described first to ninth embodiments, the FinFET is exemplified as the semiconductor device, but the described technique is not limited thereto. That is, the described technique may also be applied to a manufacturing process of a semiconductor device other than a FinFET. The described technique may also be applied to a technique for processing the substrate using a semiconductor manufacturing process such as patterning processing in a manufacturing process of a liquid-crystal display (LCD) panel, patterning processing in a manufacturing process of a solar cell and patterning processing in a manufacturing process of a power device as well as the manufacturing process of the semiconductor device.

According to the described technique, it is possible to suppress a deviation of the characteristic of the semiconductor device.

What is claimed is:

1. A method of manufacturing a semiconductor device, comprising:
(a) polishing a first silicon-containing layer formed on a substrate including a convex structure;
(b) obtaining a data representing a height distribution of a surface of the first silicon-containing layer after performing the step (a);
(c) determining a process condition based on the data for reducing a difference between a height of a surface of a laminated film at a center portion of the substrate and the height of the surface of the laminated film at a peripheral portion of the substrate, wherein the laminated film comprises the first silicon-containing layer and a second silicon-containing layer to be formed on the first silicon-containing layer in step (d), the second silicon-containing layer containing a chemical compound different from that of the first silicon-containing layer; and
(d) supplying a process gas to form the second silicon-containing layer wherein the process gas is activated such that a concentration of an active species of the process gas at the center portion of the substrate differs from a concentration of an active species at the peripheral portion of the substrate to adjust the heights of the surfaces of the laminated film according to the process condition.

2. The method of claim 1, wherein the concentration of the active species of the process gas at the center portion is adjusted to be higher than the concentration of the active species of the process gas at the peripheral portion according to the process condition when the data indicates the surface of the first silicon-containing layer at the center portion of the substrate is lower than the surface of the first silicon-containing layer at the peripheral portion of the substrate; or the concentration of the active species of the process gas at the center portion is adjusted to be lower than the concentration of the active species of the process gas at the peripheral portion according to the process condition when the data indicates the surface of the first silicon-containing layer at the peripheral portion of the substrate is lower than the surface of the first silicon-containing layer at the center portion of the substrate.

3. The method of claim 2, wherein the process gas is activated in the step (d) with a strength of a magnetic field generated at a side of the substrate being greater than that of a magnetic field generated above the substrate when the data indicates the surface of the first silicon-containing layer at the peripheral portion of the substrate is lower than the surface of the first silicon-containing layer at the center portion of the substrate.

4. The method of claim 2, wherein the process gas is activated in the step (d) with a high frequency power applied to a second coil installed at a side of the substrate being greater than a high frequency power applied to a first coil above the substrate when the data indicates the surface of the first silicon-containing layer at the peripheral portion of the substrate is lower than the surface of the first silicon-containing layer at the center portion of the substrate.

5. The method of claim 3, wherein the process gas is activated in the step (d) with a high frequency power applied to a second coil installed at a side of the substrate being greater than a high frequency power applied to a first coil above the substrate when the data indicates the surface of the first silicon-containing layer at the peripheral portion of the substrate is lower than the surface of the first silicon-containing layer at the center portion of the substrate.

6. The method of claim 2, wherein the process gas is activated in the step (d) with an electric potential applied to the peripheral portion of the substrate being lower than an electric potential applied to the center portion of the substrate when the data indicates the surface of the first silicon-containing layer at the peripheral portion of the substrate is lower than the surface of the first silicon-containing layer at the center portion of the substrate.

7. The method of claim 5, wherein the process gas is activated in the step (d) with an electric potential applied to the peripheral portion of the substrate being lower than an electric potential applied to the center portion of the substrate when the data indicates the surface of the first silicon-containing layer at the peripheral portion of the substrate is lower than the surface of the first silicon-containing layer at the center portion of the substrate.

8. The method of claim 2, wherein the process gas is activated in the step (d) with a strength of a magnetic field generated above the substrate being greater than that of a magnetic field generated at a side of the substrate when the data indicates the surface of the first silicon-containing layer at the center portion of the substrate is lower than the surface of the first silicon-containing layer at the peripheral portion of the substrate.

9. The method of claim 2, wherein the process gas is activated in the step (d) with a high frequency power applied to a first coil above the substrate being greater than a high frequency power applied to a second coil installed at a side of the substrate when the data indicates the surface of the first silicon-containing layer at the center portion of the substrate is lower than the surface of the first silicon-containing layer at the peripheral portion of the substrate.

10. The method of claim 8, wherein the process gas is activated in the step (d) with a high frequency power applied to a first coil above the substrate being greater than a high frequency power applied to a second coil installed at a side of the substrate when the data indicates the surface of the first silicon-containing layer at the center portion of the substrate is lower than the surface of the first silicon-containing layer at the peripheral portion of the substrate.

11. The method of claim 2, wherein the process gas is activated in the step (d) with an electric potential applied to the center portion of the substrate being lower than an electric potential applied to the peripheral portion of the substrate when the data indicates the surface of the first silicon-containing layer at the center portion of the substrate is lower than the surface of the first silicon-containing layer at the peripheral portion of the substrate.

12. The method of claim 8, wherein the process gas is activated in the step (d) with an electric potential applied to the center portion of the substrate being lower than an electric potential applied to the peripheral portion of the substrate when the data indicates the surface of the first silicon-containing layer at the center portion of the substrate is lower than the surface of the first silicon-containing layer at the peripheral portion of the substrate.

13. The method of claim 9, wherein the process gas is activated in the step (d) with an electric potential applied to the center portion of the substrate being lower than an electric potential applied to the peripheral portion of the substrate when the data indicates the surface of the first silicon-containing layer at the center portion of the substrate is lower than the surface of the first silicon-containing layer at the peripheral portion of the substrate.

14. The method of claim 1, wherein a characteristic of the second silicon-containing layer at the center portion of the substrate differs from that of the second silicon-containing layer at the peripheral portion of the substrate.

15. The method of claim 1, further comprising: (e) patterning the laminated film after performing the step (d).

16. The method of claim 15, further comprising: (f) removing the laminated film after performing the step (e).
